(19) United States
(12) Patent Application Publication
(10) Pub. No.: US 2026/0171983 A1
(43) Pub. Date: Jun. 18, 2026

(54) RECEIVER WITH CONFIGURABLE ENVELOPE DETECTORS

(71) Applicant: QUALCOMM Incorporated, San Diego, CA (US)

(72) Inventors: Kamala Raghavan Sadagopan, San Diego, CA (US); Yiwu Tang, San Diego, CA (US)

(21) Appl. No.: 18/982,858

(22) Filed: Dec. 16, 2024

(51) Int. Cl. H03F 3/189; H04B 1/16

(52) U.S. Cl. CPC H03F 3/189; H04B 1/1607; H03F 2200/102; H03F 2200/451

(57) ABSTRACT

An apparatus includes a plurality of envelope detectors including at least a first passive envelope detector and a second passive envelope detector coupled to the first passive envelope detector. The apparatus further includes a plurality of switches configured to couple the first passive envelope detector to the second passive envelope detector as multiple stages in a first configuration. The plurality of switches is further configured to couple the first passive envelope detector to the second passive envelope detector as a single stage in a second configuration.

### TECHNICAL FIELD

Aspects of the present disclosure relate generally to wireless communication systems, and more particularly, to a receiver within a wireless communication system.

### DESCRIPTION OF THE RELATED TECHNOLOGY

Wireless communication networks are widely deployed to provide various communication services such as voice, video, packet data, messaging, broadcast, and the like. These wireless networks may be multiple-access networks capable of supporting multiple users by sharing the available network resources.

A wireless communication network may include several components. These components may include wireless communication devices, such as base stations (or node Bs) that may support communication for a number of user equipments (UEs). A UE may communicate with a base station via downlink and uplink. The downlink (or forward link) refers to the communication link from the base station to the UE, and the uplink (or reverse link) refers to the communication link from the UE to the base station.

A base station may transmit data and control information on a downlink to a UE or may receive data and control information on an uplink from the UE. On the downlink, a transmission from the base station may encounter interference due to transmissions from neighbor base stations or from other wireless radio frequency (RF) transmitters. On the uplink, a transmission from the UE may encounter interference from uplink transmissions of other UEs communicating with the neighbor base stations or from other wireless RF transmitters. This interference may degrade performance on both the downlink and uplink.

As the demand for mobile broadband access continues to increase, the possibilities of interference and congested networks grows with more UEs accessing the long-range wireless communication networks and more short-range wireless systems being deployed in communities. Research and development continue to advance wireless technologies not only to meet the growing demand for mobile broadband access, but to advance and enhance the user experience with mobile communications.

Modern wireless communication networks are sophisticated networks that involve operation on multiple frequencies and multiple frequency ranges. RF signals in different frequencies and ranges may use different components or different configurations of components to support a device operating on these wireless communication networks and maintain high signal integrity and high bandwidth across a range of possible network conditions. The duplication of components and number of supported configurations presents challenges in designing RF systems for the UEs and BSs operating on wireless communication networks.

### SUMMARY

The systems, methods and devices of this disclosure each have several innovative aspects, no single one of which is solely responsible for the desirable attributes disclosed herein.

In some aspects, an apparatus includes a plurality of envelope detectors including at least a first passive envelope detector and a second passive envelope detector coupled to the first passive envelope detector. The apparatus further includes a plurality of switches configured to couple the first passive envelope detector to the second passive envelope detector as multiple stages in a first configuration. The plurality of switches is further configured to couple the first passive envelope detector to the second passive envelope detector as a single stage in a second configuration.

In some additional aspects, a method includes receiving, at a plurality of envelope detectors including a first passive envelope detector and a second passive envelope detector, a plurality of control signals at a plurality of switches to select a configuration corresponding to one of a first configuration or a second configuration. The first configuration configures the first passive envelope detector and the second passive envelope detector as multiple stages, and the second configuration configures the first passive envelope detector and the second passive envelope detector as a single stage. The method further includes receiving, at the plurality of envelope detectors, one or more voltages via one or more input nodes of the plurality of envelope detectors. The method further includes generating, by the plurality of envelope detectors, a wakeup signal based on the one or more voltages and further based on the selected configuration.

In some further aspects, an apparatus includes first means for passive envelope detection and second means for passive envelope detection. The apparatus further includes means for coupling the first means for passive envelope detection to the second means for passive envelope detection as multiple stages in a first configuration and for coupling the first means for passive envelope detection to the second means for passive envelope detection as a single stage in a second configuration.

While aspects and implementations are described in this application by illustration to some examples, those skilled in the art will understand that additional implementations and use cases may come about in many different arrangements and scenarios. Innovations described herein may be implemented across many differing platform types, devices, systems, shapes, sizes, and packaging arrangements. For example, aspects and/or uses may come about via integrated chip implementations and other non-module-component based devices (e.g., end-user devices, vehicles, communication devices, computing devices, industrial equipment, retail/purchasing devices, medical devices, artificial intelligence (AI)-enabled devices, etc.). While some examples may or may not be specifically directed to use cases or applications, a wide assortment of applicability of described innovations may occur. Implementations may range in spectrum from chip-level or modular components to non-modular, non-chip-level implementations and further to aggregate, distributed, or original equipment manufacturer (OEM) devices or systems incorporating one or more aspects of the described innovations. In some practical settings, devices incorporating described aspects and features may also necessarily include additional components and features for implementation and practice of claimed and described aspects. For example, transmission and reception of wireless signals necessarily includes a number of components for analog and digital purposes (e.g., hardware components including antenna, radio frequency (RF)-chains, power amplifiers, modulators, buffers, processor(s), interleavers, adders/summers, etc.). It is intended that innovations described herein may be practiced in a wide variety of devices, chip-level components, systems, distributed arrangements, end-user devices, etc. of varying sizes, shapes, and constitution.

### BRIEF DESCRIPTION OF THE DRAWINGS

FIG. 1 is a block diagram illustrating an example of a wireless communication system according to one or more aspects.

FIG. 2 is a block diagram illustrating examples of a base station and a user equipment (UE) according to one or more aspects.

FIG. 3 is a block diagram illustrating a frequency (RF) transceiver according to one or more aspects.

FIG. 4 illustrates an example of a device that includes a wakeup receiver (WUR) with configurable stages.

FIG. 5 illustrates another example of a device that includes a WUR with configurable stages.

FIG. 6 illustrates an example of an envelope detector having a differential configuration.

FIG. 7 illustrates examples of configurations that may be associated with envelope detectors.

FIG. 8 illustrates an example of an envelope detector having a single-ended configuration.

FIG. 9 illustrates examples of configurations that may be associated with envelope detectors.

FIG. 10 illustrates another example of a device that includes a WUR with configurable stages.

FIG. 11 is a flow chart illustrating an example of a method of operation of a device that includes configurable envelope detectors.

Like reference numbers and designations in the various drawings indicate like elements.

### DETAILED DESCRIPTION

Electronic devices increasingly use wireless communications to send and receive information. For example, Internet-of-Things (IoT) devices may be deployed to perform operations including inventory management, asset tracking, temperature and humidity sensing, and other operations.

IoT devices and other electronic devices may use low power (LP) and ultra lower power (ULP) techniques to facilitate such operations while also enabling mobility of the IoT devices. For example, a wakeup receiver (WUR) may use an envelope detector to detect a particular waveform and may activate other receiver components based on detection of the particular waveform. In some cases, LP and ULP techniques may limit the ability to receive signals in some circumstances, such as low amplitude signals or signals in the presence of interference or poor channel quality.

Some WURs may include a multi-stage envelope detector configuration having a fixed quantity of envelope detector stages. Such WURs may achieve automatic gain control or variable data rates by changing a gain or bandwidth of a baseband amplifier that may be coupled to an output of the envelope detector stages. Changing the gain or bandwidth of the baseband amplifier in such a manner may result in a greater bandwidth-to-gain product associated with the WURs or a greater power consumption of the WURs.

In some aspects of the disclosure, a device, such as a wakeup receiver (WUR), may include a configurable number of passive envelope detectors (also referred to as stages or passive gain stages). To illustrate, the device may include a first passive envelope detector, a second passive envelope detector, and a plurality of switches. The plurality of switches may be configured to couple the first passive envelope detector to the second passive envelope detector as multiple stages (e.g., in a series configuration) in a first configuration. The plurality of switches may be further configured to couple the first passive envelope detector to the second passive envelope detector as a single stage (e.g., in a parallel configuration) in a second configuration.

By configuring the device in such a manner, one or more receiver parameters may be adjusted. The one or more receiver parameters may include, for example, one or more of a gain, a rise time, a fall time, or a data rate associated with the device. Further, in some aspects, the one or more receiver parameters may be adjustable without changing (or without substantially changing) some other characteristics of the device, such as one or more of a power consumption of the device or an input impedance matching associated with the device. For example, the first configuration may be associated with a first gain, and the second configuration may be associated with a second gain that is different than the first gain. As another example, the first configuration may be associated with a first data rate, and the second configuration may be associated with a second data rate that is different than the first data rate. In some implementations, the first configuration and the second configuration may be associated with one or more of a common power consumption or a common input impedance matching. In some examples, by changing envelope detector rise and fall times associated with the device, a data rate (or allowable data rate) of the device may be adjusted (e.g., without substantially changing a power consumption or input impedance matching of the device). As a result, performance of the device may be improved without increasing a bandwidth-to-gain product of the device or a power consumption of the device. Further, the device may be compatible with a variety of implementations and operating conditions, such as varying interference, channel quality, process corners, temperature, and other conditions.

Further, by using passive envelope detectors, power consumption can be reduced. For example, passive envelope detectors may operate without direct current (DC) (or with a relatively small amount of DC, such as leakage current) and without being directly connected to a dedicated voltage supply or dedicated voltage “rail” (e.g., VDD). As a result, power consumption of a receiver may be reduced as compared to some other receivers, such as receivers that use active envelope detectors, which may operate using DC and which may consume a relatively large amount of power.

In addition, some features described herein may support analog gain control or mixed gain control (where gain control is performed using both analog and digital techniques) for a receiver. Such analog or mixed gain control may be performed via a programmable gain amplifier (PGA) coupled to the output of the configurable passive envelope detector stages. The PGA may be implemented as an active PGA that consumes DC power via a voltage “rail” (e.g., VDD). The gain of the PGA may be varied through an analog bias voltage or via digital control using switches or other components in and out of the amplifier circuit. In some implementations, such analog or mixed gain control may improve gain control as compared to other techniques that utilize digital-only control (e.g., by enabling a “finer” gain control as compared to a “coarse” digital-only gain control).

To further illustrate, one or more features described herein may be used in wireless communication networks, such as code division multiple access (CDMA) networks, time division multiple access (TDMA) networks, frequency division multiple access (FDMA) networks, orthogonal FDMA (OFDMA) networks, single-carrier FDMA (SC-FDMA) networks, LTE networks, GSM networks, 5^{th} Generation (5G) or new radio (NR) networks (sometimes referred to as “5G NR” networks, systems, or devices), as well as other wireless communication networks. As described herein, the terms “networks” and “systems” may be used interchangeably.

A CDMA network, for example, may implement a radio technology such as universal terrestrial radio access (UTRA), cdma2000, and the like. UTRA includes wideband-CDMA (W-CDMA) and low chip rate (LCR). CDMA2000 covers IS-2000, IS-95, and IS-856 standards.

A TDMA network may, for example implement a radio technology such as Global System for Mobile Communication (GSM). The 3rd Generation Partnership Project (3GPP) defines standards for the GSM EDGE (enhanced data rates for GSM evolution) radio access network (RAN), also denoted as GERAN. GERAN is the radio component of GSM/EDGE, together with the network that joins the base stations (for example, the Ater and Abis interfaces) and the base station controllers (A interfaces, etc.). The radio access network represents a component of a GSM network, through which phone calls and packet data are routed from and to the public switched telephone network (PSTN) and Internet to and from subscriber handsets, also known as user terminals or user equipments (UEs). A mobile phone operator's network may comprise one or more GERANs, which may be coupled with UTRANs in the case of a UMTS/GSM network. Additionally, an operator network may also include one or more LTE networks, or one or more other networks. The various different network types may use different radio access technologies (RATs) and RANs.

An OFDMA network may implement a radio technology such as evolved UTRA (E-UTRA), Institute of Electrical and Electronics Engineers (IEEE) 802.11, IEEE 802.16, IEEE 802.20, flash-OFDM and the like. UTRA, E-UTRA, and GSM are part of universal mobile telecommunication system (UMTS). In particular, long-term evolution (LTE) is a release of UMTS that uses E-UTRA. UTRA, E-UTRA, GSM, UMTS and LTE are described in documents provided from an organization named “3rd Generation Partnership Project” (3GPP), and cdma2000 is described in documents from an organization named “3rd Generation Partnership Project 2” (3GPP 2 ). These various radio technologies and standards are known or are being developed. For example, the 3GPP is a collaboration between groups of telecommunications associations that aims to define a globally applicable third generation (3G) mobile phone specification. 3GPP LTE is a 3GPP project which was aimed at improving UMTS mobile phone standard. The 3GPP may define specifications for the next generation of mobile networks, mobile systems, and mobile devices. The present disclosure may describe certain aspects with reference to LTE, 4G, or 5G NR technologies; however, the description is not intended to be limited to a specific technology or application, and one or more aspects described with reference to one technology may be understood to be applicable to another technology. Additionally, one or more aspects of the present disclosure may be related to shared access to wireless spectrum between networks using different radio access technologies or radio air interfaces.

5G networks contemplate diverse deployments, diverse spectrum, and diverse services and devices that may be implemented using an OFDM-based unified, air interface. To achieve these goals, further enhancements to LTE and LTE-A are considered in addition to development of the new radio technology for 5G NR networks. The 5G NR will be capable of scaling to provide coverage (1) to a massive Internet of things (IoTs) with an ultra-high density (e.g., ˜1 M nodes/km²), ultra-low complexity (e.g., ˜10 s of bits/sec), ultra-low energy (e.g., ˜10+ years of battery life), and deep coverage with the capability to reach challenging locations; (2) including mission-critical control with strong security to safeguard sensitive personal, financial, or classified information, ultra-high reliability (e.g., ˜99.9999% reliability), ultra-low latency (e.g., ˜1 millisecond (ms)), and users with wide ranges of mobility or lack thereof; and (3) with enhanced mobile broadband including extreme high capacity (e.g., ˜10 Tbps/km²), extreme data rates (e.g., multi-Gbps rate, 100+ Mbps user experienced rates), and deep awareness with advanced discovery and optimizations.

Devices, networks, and systems may be configured to communicate via one or more portions of the electromagnetic spectrum. The electromagnetic spectrum is often subdivided, based on frequency or wavelength, into various classes, bands, channels, etc. In 5G NR two initial operating bands have been identified as frequency range designations FR1 (410 MHz-7.125 GHz) and FR2 (24.25 GHz-52.6 GHz). The frequencies between FR1 and FR2 are often referred to as mid-band frequencies. Although a portion of FR1 is greater than 6 GHz, FR1 is often referred to (interchangeably) as a “sub-6 GHz” band in various documents and articles. A similar nomenclature issue sometimes occurs with regard to FR2, which is often referred to (interchangeably) as a “millimeter wave” (mmWave) band in documents and articles, despite being different from the extremely high frequency (EHF) band (30 GHz-300 GHz) which is identified by the International Telecommunications Union (ITU) as a “mmWave” band.

With the above aspects in mind, unless specifically stated otherwise, it should be understood that the term “sub-6 GHz” or the like if used herein may broadly represent frequencies that may be less than 6 GHz, may be within FR1, or may include mid-band frequencies. Further, unless specifically stated otherwise, it should be understood that the term “mmWave” or the like if used herein may broadly represent frequencies that may include mid-band frequencies, may be within FR2, or may be within the EHF band.

5G NR devices, networks, and systems may be implemented to use optimized OFDM-based waveform features. These features may include scalable numerology and transmission time intervals (TTIs); a common, flexible framework to efficiently multiplex services and features with a dynamic, low-latency time division duplex (TDD) design or frequency division duplex (FDD) design; and advanced wireless technologies, such as massive multiple input, multiple output (MIMO), robust mmWave transmissions, advanced channel coding, and device-centric mobility. Scalability of the numerology in 5G NR, with scaling of subcarrier spacing, may efficiently address operating diverse services across diverse spectrum and diverse deployments. For example, in various outdoor and macro coverage deployments of less than 3 GHz FDD or TDD implementations, subcarrier spacing may occur with 15 kHz, for example over 1, 5, 10, 20 MHz, and the like bandwidth. For other various outdoor and small cell coverage deployments of TDD greater than 3 GHz, subcarrier spacing may occur with 30 kHz over 80/100 MHz bandwidth. For other various indoor wideband implementations, using a TDD over the unlicensed portion of the 5 GHz band, the subcarrier spacing may occur with 60 kHz over a 160 MHz bandwidth. Finally, for various deployments transmitting with mmWave components at a TDD of 28 GHz, subcarrier spacing may occur with 120 kHz over a 500 MHz bandwidth.

The scalable numerology of 5G NR facilitates scalable TTI for diverse latency and quality of service (QoS) requirements. For example, shorter TTI may be used for low latency and high reliability, while longer TTI may be used for higher spectral efficiency. The efficient multiplexing of long and short TTIs to allow transmissions to start on symbol boundaries. 5G NR also contemplates a self-contained integrated subframe design with uplink or downlink scheduling information, data, and acknowledgement in the same subframe. The self-contained integrated subframe supports communications in unlicensed or contention-based shared spectrum, adaptive uplink or downlink that may be flexibly configured on a per-cell basis to dynamically switch between uplink and downlink to meet the current traffic needs.

For clarity, certain aspects of the apparatus and techniques may be described below with reference to example 5G NR implementations or in a 5G-centric way, and 5G terminology may be used as illustrative examples in portions of the description below; however, the description is not intended to be limited to 5G applications.

Moreover, it should be understood that, in operation, wireless communication networks adapted according to the concepts herein may operate with any combination of licensed or unlicensed spectrum depending on loading and availability. Accordingly, it will be apparent to a person having ordinary skill in the art that the systems, apparatus and methods described herein may be applied to other communications systems and applications than the particular examples provided.

While aspects and implementations are described in this application by illustration to some examples, those skilled in the art will understand that additional implementations and use cases may come about in many different arrangements and scenarios. Innovations described herein may be implemented across many differing platform types, devices, systems, shapes, sizes, packaging arrangements. For example, implementations or uses may come about via integrated chip implementations or other non-module-component based devices (e.g., end-user devices, vehicles, communication devices, computing devices, industrial equipment, retail devices or purchasing devices, medical devices, AI-enabled devices, etc.). While some examples may or may not be specifically directed to use cases or applications, a wide assortment of applicability of described innovations may occur. Implementations may range from chip-level or modular components to non-modular, non-chip-level implementations and further to aggregated, distributed, or original equipment manufacturer (OEM) devices or systems incorporating one or more described aspects. In some practical settings, devices incorporating described aspects and features may also necessarily include additional components and features for implementation and practice of claimed and described aspects. It is intended that innovations described herein may be practiced in a wide variety of implementations, including both large devices or small devices, chip-level components, multi-component systems (e.g., radio frequency (RF)-chain, communication interface, processor), distributed arrangements, end-user devices, etc. of varying sizes, shapes, and constitution.

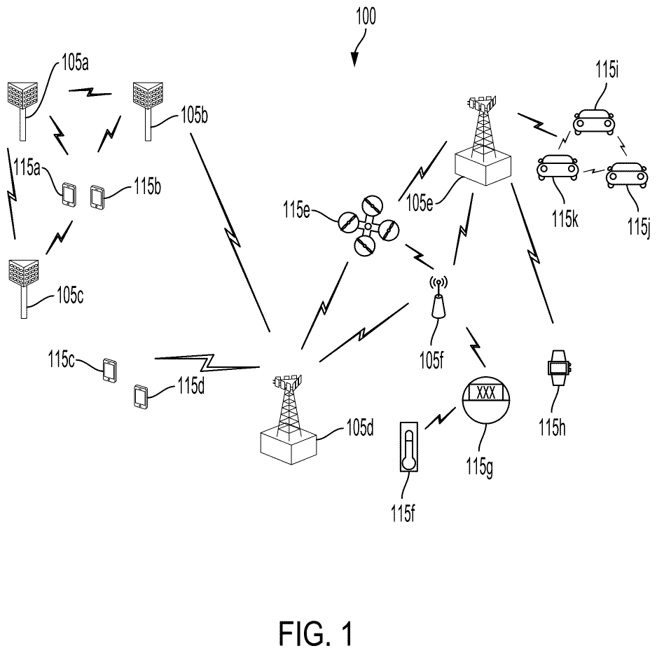

FIG. 1 is a block diagram illustrating details of an example of a wireless communication system according to one or more aspects. The wireless communication system may include wireless network 100. Wireless network 100 may, for example, include a 5G wireless network. As appreciated by those skilled in the art, components appearing in FIG. 1 are likely to have related counterparts in other network arrangements including, for example, cellular-style network arrangements and non-cellular-style-network arrangements (e.g., device to device or peer to peer or ad hoc network arrangements, etc.).

Wireless network 100 illustrated in FIG. 1 includes a number of base stations 105 and other network entities. A base station may be a station that communicates with the UEs and may also be referred to as an evolved node B (eNB), a next generation eNB (gNB), an access point, and the like. Each base station 105 may provide communication coverage for a particular geographic area. In 3GPP, the term “cell” may refer to this particular geographic coverage area of a base station or a base station subsystem serving the coverage area, depending on the context in which the term is used. In implementations of wireless network 100 herein, base stations 105 may be associated with a same operator or different operators (e.g., wireless network 100 may include a plurality of operator wireless networks). Additionally, in implementations of wireless network 100 herein, base station 105 may provide wireless communications using one or more of the same frequencies (e.g., one or more frequency bands in licensed spectrum, unlicensed spectrum, or a combination thereof) as a neighboring cell. In some examples, an individual base station 105 or UE 115 may be operated by more than one network operating entity. In some other examples, each base station 105 and UE 115 may be operated by a single network operating entity.

A base station may provide communication coverage for a macro cell or a small cell, such as a pico cell or a femto cell, or other types of cell. A macro cell generally covers a relatively large geographic area (e.g., several kilometers in radius) and may allow unrestricted access by UEs with service subscriptions with the network provider. A small cell, such as a pico cell, would generally cover a relatively smaller geographic area and may allow unrestricted access by UEs with service subscriptions with the network provider. A small cell, such as a femto cell, would also generally cover a relatively small geographic area (e.g., a home) and, in addition to unrestricted access, may also provide restricted access by UEs having an association with the femto cell (e.g., UEs in a closed subscriber group (CSG), UEs for users in the home, and the like). A base station for a macro cell may be referred to as a macro base station. A base station for a small cell may be referred to as a small cell base station, a pico base station, a femto base station or a home base station. In the example shown in FIG. 1, base stations 105d and 105e are regular macro base stations, while base stations 105a-105c are macro base stations enabled with one of 3 dimension (3D), full dimension (FD), or massive MIMO. Base stations 105a-105c take advantage of their higher dimension MIMO capabilities to exploit 3D beamforming in both elevation and azimuth beamforming to increase coverage and capacity. Base station 105f is a small cell base station which may be a home node or portable access point. A base station may support one or multiple (e.g., two, three, four, and the like) cells.

Wireless network 100 may support synchronous or asynchronous operation. For synchronous operation, the base stations may have similar frame timing, and transmissions from different base stations may be approximately aligned in time. For asynchronous operation, the base stations may have different frame timing, and transmissions from different base stations may not be aligned in time. In some scenarios, networks may be enabled or configured to handle dynamic switching between synchronous or asynchronous operations.

UEs 115 are dispersed throughout the wireless network 100, and each UE may be stationary or mobile. It should be appreciated that, although a mobile apparatus is commonly referred to as a UE in standards and specifications promulgated by the 3GPP, such apparatus may additionally or otherwise be referred to by those skilled in the art as a mobile station (MS), a subscriber station, a mobile unit, a subscriber unit, a wireless unit, a remote unit, a mobile device, a wireless device, a wireless communications device, a remote device, a mobile subscriber station, an access terminal (AT), a mobile terminal, a wireless terminal, a remote terminal, a handset, a terminal, a user agent, a mobile client, a client, a gaming device, an augmented reality device, vehicular component, vehicular device, or vehicular module, or some other suitable terminology. Within the present document, a “mobile” apparatus or UE need not necessarily have a capability to move, and may be stationary. Some non-limiting examples of a mobile apparatus, such as may include implementations of one or more of UEs 115, include a mobile, a cellular (cell) phone, a smart phone, a session initiation protocol (SIP) phone, a wireless local loop (WLL) station, a laptop, a personal computer (PC), a notebook, a netbook, a smart book, a tablet, and a personal digital assistant (PDA). A mobile apparatus may additionally be an IoT or “Internet of everything” (IoE) device such as an automotive or other transportation vehicle, a satellite radio, a global positioning system (GPS) device, a global navigation satellite system (GNSS) device, a logistics controller, a drone, a multi-copter, a quad-copter, a smart energy or security device, a solar panel or solar array, municipal lighting, water, or other infrastructure; industrial automation and enterprise devices; consumer and wearable devices, such as eyewear, a wearable camera, a smart watch, a health or fitness tracker, a mammal implantable device, gesture tracking device, medical device, a digital audio player (e.g., MP3 player), a camera, a game console, etc. ; and digital home or smart home devices such as a home audio, video, and multimedia device, an appliance, a sensor, a vending machine, intelligent lighting, a home security system, a smart meter, etc. In one aspect, a UE may be a device that includes a Universal Integrated Circuit Card (UICC). In another aspect, a UE may be a device that does not include a UICC. In some aspects, UEs that do not include UICCs may also be referred to as IoE devices. UEs 115a-115d of the implementation illustrated in FIG. 1 are examples of mobile smart phone-type devices accessing wireless network 100. A UE may also be a machine specifically configured for connected communication, including machine type communication (MTC), enhanced MTC (eMTC), narrowband IoT (NB-IoT) and the like. UEs 115e-115k illustrated in FIG. 1 are examples of various machines configured for communication that access wireless network 100.

A mobile apparatus, such as UEs 115, may be able to communicate with any type of the base stations, whether macro base stations, pico base stations, femto base stations, relays, and the like. In FIG. 1, a communication link (represented as a lightning bolt) indicates wireless transmissions between a UE and a serving base station, which is a base station designated to serve the UE on the downlink or uplink, or desired transmission between base stations, and backhaul transmissions between base stations. UEs may operate as base stations or other network nodes in some scenarios. Backhaul communication between base stations of wireless network 100 may occur using wired or wireless communication links.

In operation at wireless network 100, base stations 105a-105c serve UEs 115a and 115b using 3D beamforming and coordinated spatial techniques, such as coordinated multipoint (CoMP) or multi-connectivity. Macro base station 105d performs backhaul communications with base stations 105a-105c, as well as small cell, base station 105f. Macro base station 105d also transmits multicast services which are subscribed to and received by UEs 115c and 115d. Such multicast services may include mobile television or stream video, or may include other services for providing community information, such as weather emergencies or alerts (e.g., Amber alerts or gray alerts).

Wireless network 100 of implementations supports mission critical communications with ultra-reliable and redundant links for mission critical devices, such as UE 115e, which is a drone. Redundant communication links with UE 115e include from macro base stations 105d and 105e, as well as small cell base station 105f. Other machine type devices, such as UE 115f (thermometer), UE 115g (smart meter), and UE 115h (wearable device) may communicate through wireless network 100 either directly with base stations, such as small cell base station 105f, and macro base station 105e, or in multi-hop configurations by communicating with another user device which relays its information to the network, such as UE 115f communicating temperature measurement information to the smart meter, UE 115g, which is then reported to the network through small cell base station 105f. Wireless network 100 may also provide additional network efficiency through dynamic, low-latency TDD communications or low-latency FDD communications, such as in a vehicle-to-vehicle (V2V) mesh network between UEs 115i-115k communicating with macro base station 105e.

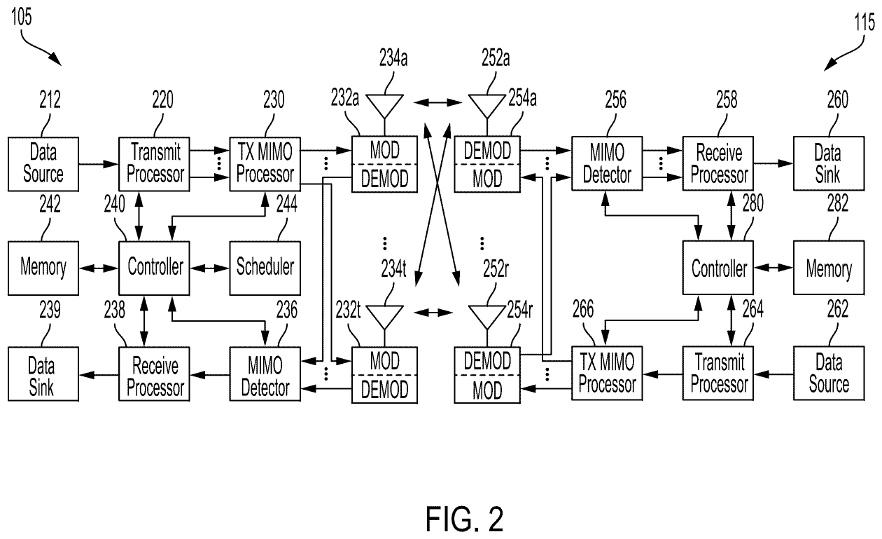

FIG. 2 is a block diagram illustrating examples of base station 105 and UE 115 according to one or more aspects. Base station 105 and UE 115 may be any of the base stations and one of the UEs in FIG. 1. For a restricted association scenario (as mentioned above), base station 105 may be small cell base station 105f in FIG. 1, and UE 115 may be UE 115c or 115d operating in a service area of base station 105f, which in order to access small cell base station 105f, would be included in a list of accessible UEs for small cell base station 105f. Base station 105 may also be a base station of some other type. As shown in FIG. 2, base station 105 may be equipped with antennas 234a through 234t, and UE 115 may be equipped with antennas 252a through 252r for facilitating wireless communications.

At base station 105, transmit processor 220 may receive data from data source 212 and control information from controller 240, such as a processor. The control information may be for a physical broadcast channel (PBCH), a physical control format indicator channel (PCFICH), a physical hybrid-ARQ (automatic repeat request) indicator channel (PHICH), a physical downlink control channel (PDCCH), an enhanced physical downlink control channel (EPDCCH), an MTC physical downlink control channel (MPDCCH), etc. The data may be for a physical downlink shared channel (PDSCH), etc. Additionally, transmit processor 220 may process (e.g., encode and symbol map) the data and control information to obtain data symbols and control symbols, respectively. Transmit processor 220 may also generate reference symbols, e.g., for the primary synchronization signal (PSS) and secondary synchronization signal (SSS), and cell-specific reference signal. Transmit (TX) MIMO processor 230 may perform spatial processing (e.g., precoding) on the data symbols, the control symbols, or the reference symbols, if applicable, and may provide output symbol streams to modulators (MODs) 232a through 232t. For example, spatial processing performed on the data symbols, the control symbols, or the reference symbols may include precoding. Each modulator 232 may process a respective output symbol stream (e.g., for OFDM, etc.) to obtain an output sample stream. Each modulator 232 may additionally or alternatively process (e.g., convert to analog, amplify, filter, and upconvert) the output sample stream to obtain a downlink signal. Downlink signals from modulators 232a through 232t may be transmitted via antennas 234a through 234t, respectively.

At UE 115, antennas 252a through 252r may receive the downlink signals from base station 105 and may provide received signals to demodulators (DEMODs) 254a through 254r, respectively. Each demodulator 254 may condition (e.g., filter, amplify, downconvert, and digitize) a respective received signal to obtain input samples. Each demodulator 254 may further process the input samples (e.g., for OFDM, etc.) to obtain received symbols. MIMO detector 256 may obtain received symbols from demodulators 254a through 254r, perform MIMO detection on the received symbols if applicable, and provide detected symbols. Receive processor 258 may process (e.g., demodulate, deinterleave, and decode) the detected symbols, provide decoded data for UE 115 to data sink 260, and provide decoded control information to controller 280, such as a processor.

On the uplink, at UE 115, transmit processor 264 may receive and process data (e.g., for a physical uplink shared channel (PUSCH)) from data source 262 and control information (e.g., for a physical uplink control channel (PUCCH)) from controller 280. Additionally, transmit processor 264 may also generate reference symbols for a reference signal. The symbols from transmit processor 264 may be precoded by TX MIMO processor 266 if applicable, further processed by modulators 254a through 254r (e.g., for SC-FDM, etc.), and transmitted to base station 105. At base station 105, the uplink signals from UE 115 may be received by antennas 234, processed by demodulators 232, detected by MIMO detector 236 if applicable, and further processed by receive processor 238 to obtain decoded data and control information sent by UE 115. Receive processor 238 may provide the decoded data to data sink 239 and the decoded control information to controller 240.

Controllers 240 and 280 may direct the operation at base station 105 and UE 115, respectively. Controller 240 or other processors and modules at base station 105 or controller 280 or other processors and modules at UE 115 may perform or direct the execution of various processes for the techniques described herein. Memories 242 and 282 may store data and program codes for base station 105 and UE 115, respectively. Scheduler 244 may schedule UEs for data transmission on the downlink or the uplink.

In some cases, UE 115 and base station 105 may operate in a shared radio frequency spectrum band, which may include licensed or unlicensed (e.g., contention-based) frequency spectrum. In an unlicensed frequency portion of the shared radio frequency spectrum band, UEs 115 or base stations 105 may traditionally perform a medium-sensing procedure to contend for access to the frequency spectrum. For example, UE 115 or base station 105 may perform a listen-before-talk or listen-before-transmitting (LBT) procedure such as a clear channel assessment (CCA) prior to communicating in order to determine whether the shared channel is available. In some implementations, a CCA may include an energy detection procedure to determine whether there are any other active transmissions. For example, a device may infer that a change in a received signal strength indicator (RSSI) of a power meter indicates that a channel is occupied. Specifically, signal power that is concentrated in a certain bandwidth and exceeds a predetermined noise floor may indicate another wireless transmitter. A CCA also may include detection of specific sequences that indicate use of the channel. For example, another device may transmit a specific preamble prior to transmitting a data sequence. In some cases, an LBT procedure may include a wireless node adjusting its own backoff window based on the amount of energy detected on a channel or the acknowledge/negative-acknowledge (ACK/NACK) feedback for its own transmitted packets as a proxy for collisions.

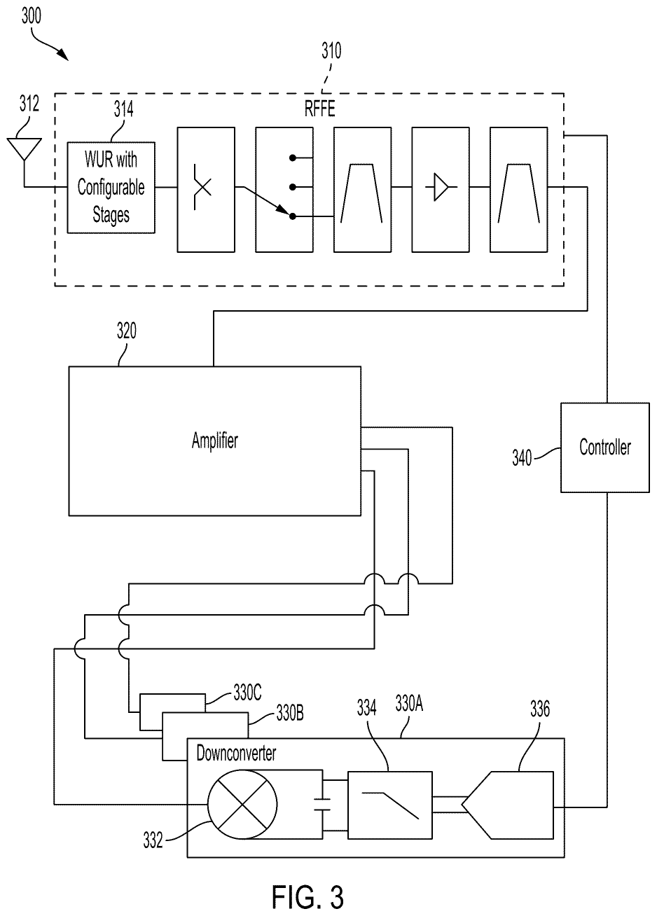

FIG. 3 is a block diagram illustrating a receiver circuit 300 according to one or more aspects. In some embodiments, the receiver circuit 300 may be part of a converged sub-6 Ghz and mmWave radio frequency (RF) transceiver, a sub-6 GHz radio frequency (RF) transceiver, or a mmWave radio frequency (RF) transceiver. In some embodiments, portions or all of the RF transceiver of FIG. 3 may be located in a single integrated circuit (IC) sharing a common substrate. The receiver circuit 300 may include an antenna 312 to receive radio frequency (RF) signals, such as a phase antenna array. The antenna 312 is coupled to a RF front-end (RFFE) 310, which may include duplexers, SAW filters, switches, LNAs, and/or other transmit or receive circuits for conditioning signals received from the antenna 312. In some embodiments, the RFFE 310 may include separate circuits for conditioning or otherwise processing sub-6 GHz signals, mmWave signals, satellite signals, and/or other signals. For example, the RFFE 310 may include a first plurality of circuits for conditioning a sub-6 GHz signal for further processing by other circuitry and a second plurality of circuits for conditioning a mmWave RF signal for further processing by other circuitry. The output of the RFFE 310 in this example may be a input RF signal to other circuitry comprising the conditioned sub-6 GHz signal and a conditioned mmWave IF signal. The RFFE 310 is coupled to an amplifier 320, such as a low noise amplifier (LNA). The amplifier 320 is coupled to one or more downconverters 330A, 330B, and 330C. Each of the downconverters 330A, 330B, and 330C may include mixers 332, baseband filters (BBFs) 334, and/or analog-to-digital converters (ADCs) 336. The downconverters 330A, 330B, 330C may include one or more harmonic rejection mixers (HRMs). In some embodiments, the amplifier 320 is shared on an IC with one or more of the RFFE 310 and/or the downconverters 330A, 330B, and 330C.

A controller 340 may detect conditions in the RF signal received from the antenna 312 or receive information regarding the carrier configuration from higher levels, such as a MAC layer or network layer. The controller 340 may configure components of the receiver circuit 300 to activate, deactivate, or control portions of the receiver circuit 300 to process an input RF signal. In some embodiments, the controller 340 configures components to reduce interference between bands within the receiver circuit 300. In some embodiments, the controller 340 may configure one or more components described herein, such as one or more components of the RFFE 310, one or more components within the downconverters 330A, 330B, and 330C, one or more other components, or a combination thereof.

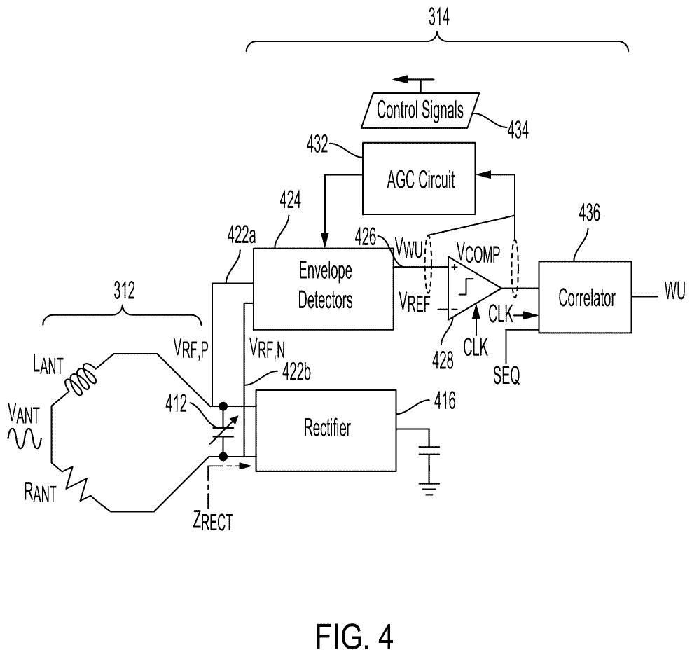

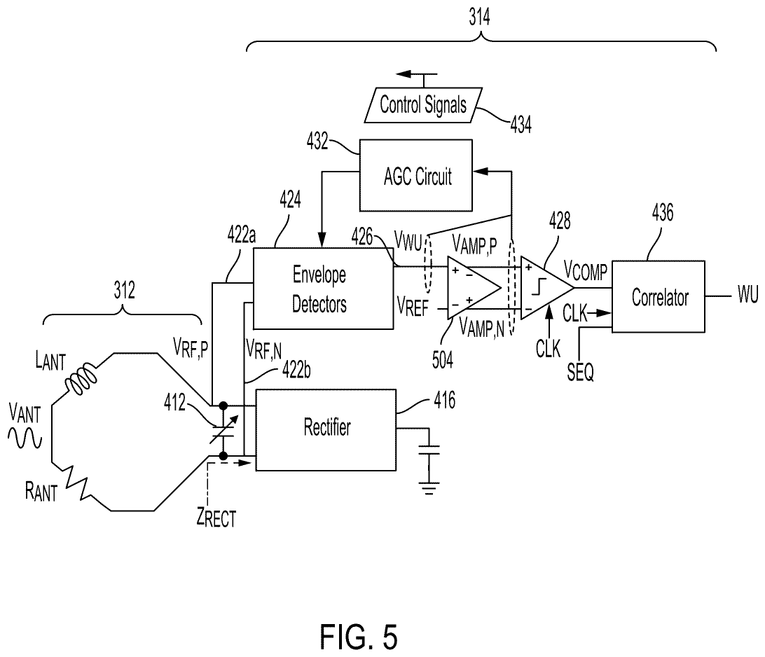

In some examples, the RFFE 310 may include a wakeup receiver (WUR) 314 with configurable stages. The WUR 314 may be coupled to the antenna 312. The WUR 314 may be coupled to one or more other components, such as one or more components of the RFFE 310 or the amplifier 320. Some illustrative examples of features that may be associated with the WUR 314 are described further with reference to FIGS. 4 and 5.

In addition, although the WUR 314 may be depicted or described in connection with some devices and systems for illustration, other devices and systems are also within the scope of the disclosure. For example, although the example of FIG. 3 may depict a transceiver architecture, and although some examples may be described with reference to 5G NR wireless communication systems, other examples may use different implementations of the WUR 314. In one example, the WUR 314 may be included in another device, such as an ambient Internet-of-Things (IoT) device or in a coin-cell battery powered device. In some such examples, the device may use the WUR 314 to monitor for a wakeup signal and may activate one or more components of the device upon detecting the wakeup signal. Upon activating the one or more components, the device may perform one or more operations, such as by transmitting data (e.g., data indicating a sensor reading). In some such implementations, power may be “harvested” from the wakeup signal and may be used as a power source of the device, such as a primary power source of the device. Other implementations are also within the scope of the disclosure and may include, for example, other devices that utilize low power consumption in a standby mode of operation.

FIG. 4 illustrates an example of a device that includes a WUR 314 with configurable stages. The WUR 314 may be coupled to one or more antennas, such as the antenna 312. In some implementations, the antenna 312 may have a loop configuration and may be associated with an inductance L_{ANT}, a resistance R_{ANT}, and a signal V_{ANT}. In some implementations, the antenna 312 may be coupled to a tuner circuit 412. The tuner circuit 412 may be coupled to the antenna 312 and to the WUR 314.

The WUR 314 may include a rectifier 416. The rectifier 416 may be coupled to the antenna 312 and to the tuner circuit 412. In some examples, the rectifier 416 may correspond to a multi-stage rectifier, a capacitive rectifier, or another type of rectifier. In some examples, the rectifier 416 may be associated with an input impedance Z_{RECT}. The rectifier 416 may selectively provide power to some load represented in the figure as a capacitor (e.g., to a battery or to some further circuitry).

The WUR 314 may further include envelope detectors 424. The envelope detectors 424 may be coupled to the antenna 312, to the tuner circuit 412, and to the rectifier 416 (e.g., via input nodes 422a and 422b). In some implementations, the envelope detectors 424 may have a differential configuration or a single-ended configuration, as described further below.

The WUR 314 may further include a comparator 428 coupled to the envelope detectors 424, an automatic gain control (AGC) circuit 432 coupled in a feedback path between the comparator 428 and the envelope detectors 424, and a correlator 436 coupled to the comparator 428. The envelope detectors 424 may be coupled to the comparator 428 via an output node 426. In some examples, the output node 426 may be coupled to (or may be selectively couplable to) outputs of at least some of the envelope detectors 424, as explained further below.

During operation, the antenna 312 may receive one or more signals. In some implementations, the antenna 312 may generate differential voltages V_{RF,P} P and V_{RF,N} representing a received signal. In some other examples, the antenna 312 may generate a single-ended voltage representing a received signal. In some implementations, the rectifier 416 may perform rectification of the differential voltages V_{RF,P} P and V_{RF,N}.

The envelope detectors 424 may receive the differential voltages V_{RF,P} P and V_{RF,N}. The envelope detectors 424 may generate a wakeup signal V_{WU} based on the differential voltages V_{RF,P} and V_{RF,N}. Further, the envelope detectors 424 may be configurable (e.g., by the AGC circuit 432), as described further below. To illustrate, the AGC circuit 432 (or another device) may provide control signals 434 to the envelope detectors 424 to configure a quantity of stages of the envelope detectors 424, as described further below.

The comparator 428 may receive the wakeup signal V_{WU} and may also receive a reference voltage VREF. In some examples, the comparator 428 may include a non-inverting input configured to receive the wakeup signal V_{WU} and may further include an inverting input configured to receive the reference voltage V_{REF}. The comparator 428 may also receive a clock signal CLK. The comparator 428 may generate a comparison signal V_{COMP} based on a comparison of the wakeup signal V_{WU} and the reference voltage V_{REF}. In some examples, the AGC circuit 432 may receive one or more of the wakeup signal V_{WU} or the comparison signal V_{COMP} and may configure the envelope detectors 424 based on one or more of the wakeup signal V_{WU} or the comparison signal V_{COMP}.

The correlator 436 may receive the comparison signal V_{COMP}, the clock signal CLK, and a reference sequence SEQ. The correlator 436 may generate a wakeup indicator WU based on the comparison signal V_{COMP} and the reference sequence SEQ. The wakeup signal WU may have a value indicating whether one or more other device components should “wake up,” such as by transitioning from a sleep or standby mode to an active mode of operation.

In some examples, WUR 314 of FIG. 4 may exclude a baseband amplifier. To illustrate, the WUR 314 may selectively configure the envelope detectors 424 to achieve gain adjustment instead of using a baseband amplifier for gain adjustment. Accordingly, by performing gain adjustment based on a configured quantity of stages of the WUR 314, a baseband amplifier may be omitted from the WUR 314, which may reduce power consumption and cost. Other examples are also within the scope of the disclosure. For example, in some implementations, the WUR 314 may include one or more baseband amplifiers, such as described further with reference to the example of FIG. 5.

FIG. 5 illustrates another example of a device that includes a WUR 314 with configurable stages. The device of FIG. 5 may include one or more components described with reference to FIG. 4, such as the antenna 312 and the WUR 314. Further, the device of FIG. 5 may further include a baseband amplifier 504. The baseband amplifier 504 may be coupled to the envelope detectors 424 and to the comparator 428.

During operation, the baseband amplifier 504 may receive the wakeup signal V_{WU} from the envelope detectors 424. The baseband amplifier 504 may also receive a reference voltage V_{REF}. The baseband amplifier 504 may generate a differential output V_{AMP,P} and V_{AMP,N} and may provide the differential V_{AMP,P} and V_{AMP,N} and to the comparator 428. The comparator 428 may generate the comparison signal V_{COMP} based on the differential output V_{AMP,P} and V_{AMP,N}. The correlator 436 may generate the wakeup indicator WU based on the comparison signal V_{COMP} and the reference sequence SEQ.

In connection with FIGS. 4 and 5, one or more of the devices of FIG. 4 or the device of FIG. 5 may include an energy harvester. In some implementations, the energy harvester may be configured to receive ambient wireless signals and to “harvest” energy from the ambient wireless signals. In an example, the rectifier 416 may include or may be coupled to an energy harvester. Further, energy generated by the energy harvester may be provided to one or more other device components, such as, for example, one or more of the comparator 428, the AGC circuit 432, the correlator 436, or the baseband amplifier 504. To further illustrate, in one example, a device may use such harvested energy as a primary power source of the device, such as where the device includes or corresponds to a tag that is powered by the harvested energy. In some examples, the device may use the harvested energy to transmit a sensor reading or other data, such as to a base station, an access point, or one or more other devices. As an illustrative example, the UE 115 may correspond to an ambient IoT device that uses the harvested energy to transmit a signal (e.g., the sensor reading or other data) via one or more components illustrated in FIG. 2.

The example of FIG. 5 illustrates that a WUR may include a baseband amplifier, such as the baseband amplifier 504. In some implementations, the baseband amplifier 504 may enable gain adjustment for the WUR 314 alternatively or in addition to gain adjustment performed by configuring the quantity of stages of the WUR 314 via the envelope detectors 424.

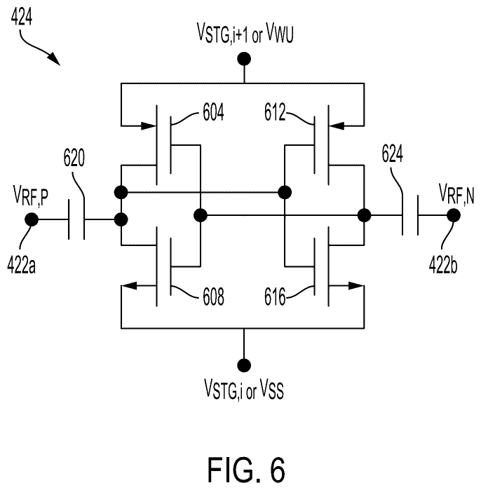

FIG. 6 illustrates an example of an envelope detector 424 having a differential configuration. In the example of FIG. 6, the envelope detector 424 may include a transistor 604, a transistor 608, a transistor 612, and a transistor 616. In some examples, the transistors 604 and 608 may form a first inverter that is cross-coupled to a second inverter formed by the transistors 612 and 616. In some examples, the transistors 604 and 612 may correspond to p-type transistors, and the transistors 608 and 616 may correspond to n-type transistors.

The envelope detector 424 may include a capacitor 620 and a capacitor 624. The capacitor 620 may be coupled to the input node 422a, and the capacitor 624 may be coupled to the input node 422b. The capacitor 620 may be configured to receive the voltage V_{RF,P} via the input node 422a, and the capacitor 624 may be configured to receive the voltage V_{RF,N} via the input node 422b.

The transistors 604, 608, 612, and 616 may receive the voltages V_{RF,P} and V_{RF,N}. For example, a first terminal of the capacitor 620 may be coupled to receive the voltage V_{RF,P}. A second terminal of the capacitor 620 may be coupled to a drain terminal of the transistor 604, to a drain terminal of the transistor 608, to a gate terminal of the transistor 612, and to a gate terminal of the transistor 616. In this example, the drain terminals of the transistors 604, 608 and the gate terminals of the transistors 612, 616 may be configured to receive the voltage V_{RF,P} via the capacitor 620. As another example, a first terminal of the capacitor 624 may be coupled to receive the voltage V_{RF,N}. A second terminal of the capacitor 624 may be coupled to a drain terminal of the transistor 612, to a drain terminal of the transistor 616, to a gate terminal of the transistor 604, and to a gate terminal of the transistor 608. In this example, the drain terminals of the transistors 612, 616 and the gate terminals of the transistors 604, 608 may be configured to receive the voltage V_{RF,N} via the capacitor 624.

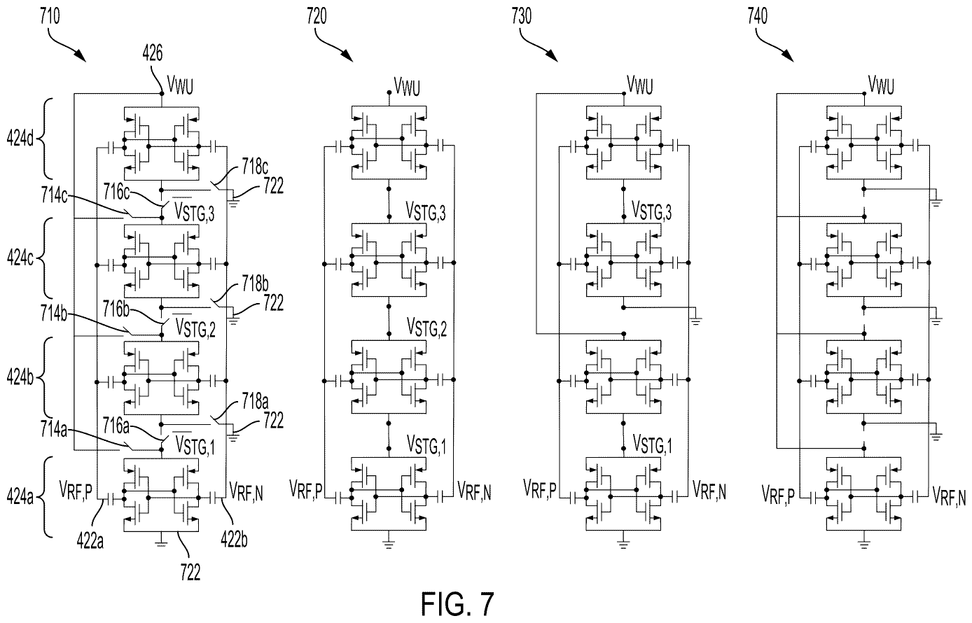

During operation, an envelope detector 424 may receive a voltage V_{STG,i} i from another envelope detector 424 or may receive a reference voltage (e.g., V_{SS} via a ground node). Further, an envelope detector 424 may provide a voltage V_{STG,i+1} to another envelope detector 424 or may generate the wakeup signal V_{WU}. In such examples, i may indicate an index value associated with an envelope detector 424, and i+1 may indicate an index value associated with another envelope detector 424. To further illustrate, some example configurations of envelope detectors 424 are described further with reference to FIG. 7.

FIG. 7 illustrates examples of configurations 710, 720, 730, and 740 that may be associated with envelope detectors 424a, 424b, 424c, and 424d. In some examples, the envelope detectors 424a-d may be included in the WUR 314, such as in the envelope detectors 424 of FIG. 4, in the envelope detectors 424 of FIG. 5, or both. Although the example of FIG. 7 illustrates four envelope detectors, in other examples, a different quantity of envelope detectors may be implemented (e.g., two envelope detectors, three envelope detectors, five envelope detectors, or another quantity of envelope detectors).

Each of the envelope detectors 424a-d may be associated with (e.g., may include or may be coupled to) one or more switches. For example, the envelope detectors 424a-b may be coupled to a switch 716a. A first terminal of the switch 716a may be coupled to an output of the envelope detector 424a and to a first terminal of a switch 714a. A second terminal of the switch 716a may be coupled to an input of the envelope detector 424b. A second terminal of the switch 714a may be coupled to the output node 426. As additional examples, the envelope detectors 424b-c may be coupled to switches 714b and 716b, and the envelope detectors 424c-d may be coupled to switches 714c and 716c.

Further, the envelope detectors 424a-b may be coupled to a first terminal of a switch 718a, the envelope detectors 424b-c may be coupled to a first terminal of a switch 718b, and the envelope detectors 424c-d may be coupled to a first terminal of a switch 718c. The switches 718a-c may each include a respective second terminal coupled to one or more ground nodes, such as a ground node 722.

During operation, the switches 714a-c, 716a-c, and 718a-c may be operated (e.g., activated or deactivated) to configure a quantity of stages of a WUR, such as the WUR 314. In some examples, the switches 714a-c, 716a-c, and 718a-c may be coupled to a device (such as a controller or other device) that provides control signals to the switches 714a-c, 716a-c, and 718a-c. In some implementations, the controller may correspond to the AGC circuit 432, and the AGC circuit 432 may control the switches 714a-c, 716a-c, and 718a-c via the control signals 434 to determine one or more of a rise time associated with the wakeup signal V_{WU}, a fall time associated with the wakeup signal V_{WU}, or a gain associated with the WUR 314 (e.g., a gain applied by the WUR 314 to the differential voltage V_{RF,P} V_{RF,N} to generate the wakeup signal V_{WU}).

To illustrate, in the configuration 720, each of the switches 714a-c may be deactivated (e.g., opened) to decouple outputs of the envelope detectors 424a-c from the output node 426, respectively. By decoupling outputs of the envelope detectors 424e-h from the output node 426, the envelope detectors 424a-c may be selectively decoupled from one or more other components of the WUR 314, such as the comparator 428 of FIG. 4 or the baseband amplifier 504 of FIG. 5. Further, in the configuration 720, the switches 716a-c may be activated (e.g., closed) to couple outputs of the envelope detectors 424a-c to inputs of the envelope detectors 424b-d, respectively. In the configuration 720, the switches 718a-c may be deactivated (e.g., opened) to decouple the envelope detectors 424a-c from the ground node 722.

In the configuration 720, activation of the switches 716a-c may form serial connections between the envelope detectors 424a-d. For example, the switch 716a may form a serial connection between the envelope detectors 424a-b. As additional examples, the switch 716b may form a serial connection between the envelope detectors 424b-c, and the switch 716c may form a serial connection between the envelope detectors 424c-d. The envelope detector 424a may provide a voltage V_{STG,1} to the envelope detector 424b, which may provide a voltage V_{STG,2} to the envelope detector 424c. The envelope detector 424c may provide a voltage V_{STG,3} to the envelope detector 424d.

The configuration 720 may be referred to as, or may correspond to, a four-stage configuration. For example, in the configuration 720, the envelope detectors 424a-d may be coupled to one another via serial connections formed by activation of the switches 716a-c and deactivation of the switches 714a-c and 718a-c. The configuration 720 may increase gain and increase rise time (and fall time) as compared to the configurations 730 and 740. The configuration 720 may be associated with a gain that is greater than a gain associated with the configuration 730 and that is greater than a gain associated with the configuration 740. Further, the configuration 720 may be associated with a rise time (and fall time) that is greater than a rise time (and fall time) associated with the configuration 730 and that is greater than a rise time (and fall time) associated with the configuration 740.

In the configuration 730, at least some envelope detectors may be coupled to one another via a serial connection. For example, the switch 714a may be deactivated to decouple the output of the envelope detector 424a from the output node 426, and the switch 716a may be activated to couple the output of the envelope detector 424a to the input of the envelope detector 424b. In this example, the envelope detector 424a may be coupled to the envelope detector 424b via a serial connection. As another example, the switch 714c may be deactivated to decouple the output of the envelope detector 424c from the output node 426, and the switch 716c may be activated to couple the output of the envelope detector 424c to the input of the envelope detector 424d. In this example, the envelope detector 424c may be coupled to the envelope detector 424d via a serial connection.

Further, in the configuration 730, at least some envelope detectors may be coupled to one another in parallel. For example, the switch 716b may be deactivated to decouple the output of the envelope detector 424b from the input of the envelope detector 424c, and the switch 714b may be activated to couple the output of the envelope detector 424b to the output node 426. In this example, the envelope detectors 424a-b may be coupled in parallel to the envelope detectors 424c-d. The envelope detector 424a may provide the voltage V_{STG,1} to the envelope detector 424b, and the envelope detector 424c may provide the voltage V_{STG,3} to the envelope detector 424d.

In addition, in the configuration 730, the switches 718a and 718c may be deactivated to decouple the envelope detectors 424b and 424d from the ground node 722. The switch 718b may be activated to couple the envelope detector 424c to the ground node 722.

The configuration 730 may be referred to as, or may correspond to, a two-stage configuration. In a two-stage configuration, multiple envelope detectors 424 may be configurable as a single two-stage envelope detector. For example, in the configuration 730, the envelope detectors 424a-b may be coupled to one another via the switch 716a and may correspond to a first two-stage envelope detector. Further, the envelope detectors 424c-d may be coupled to one another via the switch 716c and may correspond to a second two-stage envelope detector in parallel with the first two-stage envelope detector formed by the envelope detectors 424a-b. The gain associated with the configuration 730 may be less than the gain associated with the configuration 720 and may be greater than the gain associated with the configuration 740. Further, the rise time (and fall time) associated with the configuration 730 may be less than the rise time (and fall time) associated with the configuration 720 and may be greater than the rise time (and fall time) associated with the configuration 740.

In the configuration 740, the envelope detectors 424a-d may be coupled in parallel to one another. For example, the switches 716a-c may be deactivated to decouple outputs of the envelope detectors 424a-c from inputs of the envelope detectors 424b-d, and outputs of the envelope detectors 424a-d may be coupled to the output node 426 (e.g., where the envelope detectors 424a-c are coupled to the output node 426 via the activation of the switches 714a-c). Further, input nodes of the envelope detectors 424a-d may be coupled to a ground node (GND) (such as the ground node 722) through switches 718a-c.

The configuration 740 may be referred to as, or may correspond to, a single-stage configuration or a one-stage configuration. For example, in the configuration 740, the envelope detectors 424a-d may be coupled in parallel with one another, which may decrease gain and decrease rise time (and fall time) as compared to the configurations 720 and 730. The gain associated with the configuration 740 may be less than the gain associated with the configuration 720 and may be less than the gain associated with the configuration 730. Further, the rise time (and fall time) associated with the configuration 740 may be less than the rise time (and fall time) associated with the configuration 720 and may be less than the rise time (and fall time) associated with the configuration 730.

In some examples, the AGC circuit 432 may select among any of the configurations of FIG. 7 to adjust one or more of a gain associated with the WUR 314 (e.g., a gain applied by the WUR 314 to the differential voltage V_{RF,P}, V_{RF,N} to generate the wakeup signal V_{WU}), a rise time associated with the wakeup signal V_{WU}, or a fall time associated with the wakeup signal V_{WU}. For example, in some implementations, if the gain of the WUR 314 fails to exceed a threshold gain, the AGC circuit 432 may increase the gain, such as by reconfiguring the WUR 314 from the configuration 730 to the configuration 720, or from the configuration 740 to the configuration 720 or the configuration 730. As another example, in some implementations, if the rise time (or fall time) of the WUR 314 exceeds a threshold rise time (or fall time), the AGC circuit 432 may decrease the rise time (or fall time), such as by reconfiguring the WUR 314 from the configuration 720 to the configuration 730 or the configuration 740, or from the configuration 730 to the configuration 740.

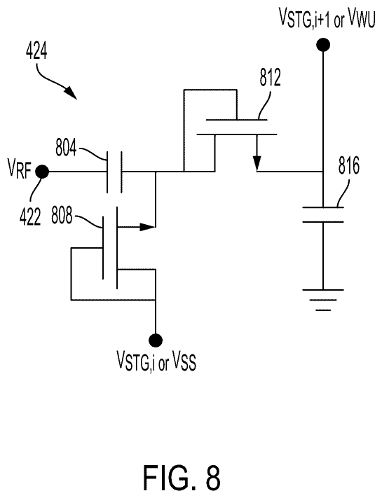

FIG. 8 illustrates an example of an envelope detector 424 having a single-ended configuration. In the example of FIG. 8, the envelope detector 424 may include a capacitor 804, a transistor 808, a transistor 812, and a capacitor 816. The capacitor may be coupled to an input node 422, to the transistor 808, and to the transistor 812. The transistor 812 may be coupled to the capacitor 804, to the transistor 808, and to the capacitor 816. The capacitor 816 may be coupled to a ground node.

To further illustrate, a first terminal of the capacitor 804 may be coupled to receive a single-ended voltage, such as V_{RF}. A second terminal of the capacitor 804 may be coupled to a source terminal of the transistor 808, to a drain terminal of the transistor 812, and to a gate terminal of the transistor 812. A first terminal of the capacitor 816 may be coupled to a drain terminal of the transistor 812, and a second terminal of the capacitor 816 may be coupled to a ground node. A gate terminal of the transistor 808 may be coupled (e.g., shorted or “tied”) to a drain terminal of the transistor 808, and a gate terminal of the transistor 812 may be coupled (e.g., shorted or “tied”) to a drain terminal of the transistor 812.

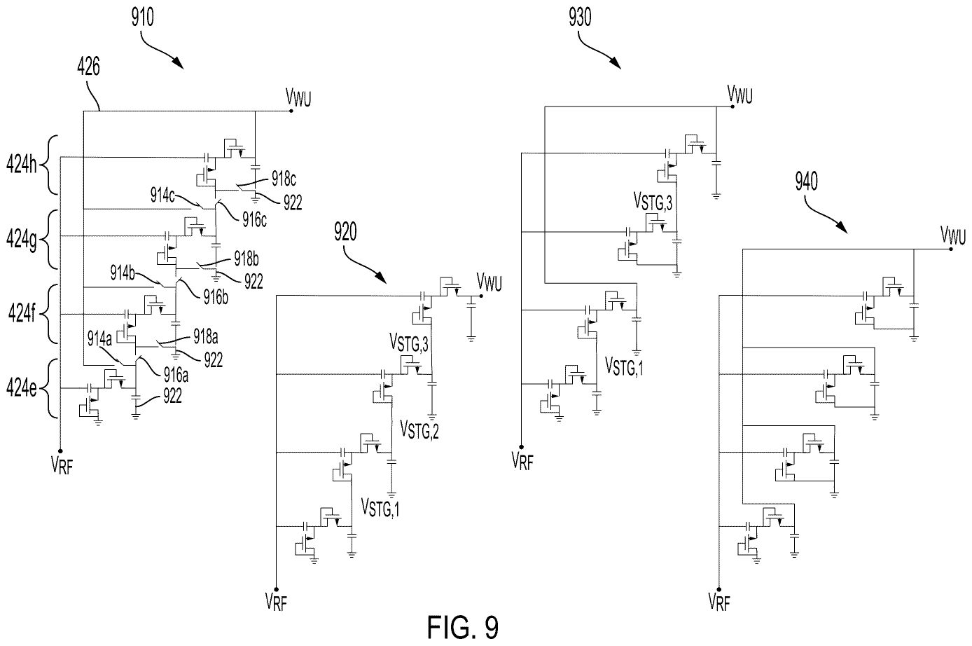

During operation, the input node 422 may receive a single-ended voltage, such as V_{RF}. Further, each envelope detector 424 may receive a voltage V_{STG,i} from another envelope detector 424 or may receive a reference voltage (e.g., V_{SS} via a ground node). Further, an envelope detector 424 may provide a voltage V_{STG,i+1} to another envelope detector 424 or may generate the wakeup signal V_{WU}. In such examples, i may indicate an index value associated with an envelope detector 424, and i+1 may indicate an index value associated with another envelope detector 424. To further illustrate, some example configurations of envelope detectors 424 are described further with reference to FIG. 9.

FIG. 9 illustrates examples of configurations 910, 920, 930, and 940 that may be associated with envelope detectors 424e, 424f, 424g, and 424h. In some examples, the envelope detectors 424e-h may be included in the WUR 314, such as in the envelope detectors 424 of FIG. 4, in the envelope detectors 424 of FIG. 5, or both. Although the example of FIG. 9 illustrates four envelope detectors, in other examples, a different quantity of envelope detectors may be implemented (e.g., two envelope detectors, three envelope detectors, five envelope detectors, or another quantity of envelope detectors).

Each of the envelope detectors 424e-h may be associated with (e.g., may include or may be coupled to) one or more switches. For example, the envelope detectors 424e-f may be coupled to a switch 916a. A first terminal of the switch 916a may be coupled to an output of the envelope detector 424e and to a first terminal of a switch 914a. A second terminal of the switch 916a may be coupled to an input of the envelope detector 424f. A second terminal of the switch 914a may be coupled to the output node 426. As additional examples, the envelope detectors 424f-g may be coupled to switches 914b and 916b, and the envelope detectors 424g-h may be coupled to switches 914c and 916c.

Further, the envelope detectors 424e-f may be coupled to a first terminal of a switch 918a, the envelope detectors 424f-g may be coupled to a first terminal of a switch 918b, and the envelope detectors 424g-h may be coupled to a first terminal of a switch 918c. The switches 918a-c may each include a respective second terminal coupled to coupled to one or more ground nodes, such as a ground node 722.

During operation, the switches 914a-c, 916a-c, and 918a-c may be operated (e.g., activated or deactivated) to configure a quantity of stages of a WUR, such as the WUR 314. In some examples, the switches 914a-c, 916a-c, and 918a-c may be coupled to a device (such as a controller or other device) that provides control signals to the switches 914a-c, 916a-c, and 918a-c. In some implementations, the controller may correspond to the AGC circuit 432, and the AGC circuit 432 may control the switches 914a-c, 916a-c, and 918a-c via the control signals 434 to determine one or more of a rise time, a fall time, or a gain associated with the WUR 314.

To illustrate, in the configuration 920, each of the switches 914a-c may be deactivated (e.g., opened) to decouple outputs of the envelope detectors 424e-h from the output node 426, respectively. By decoupling outputs of the envelope detectors 424e-h from the output node 426, the envelope detectors 424e-h may be selectively decoupled from one or more other components of the WUR 314, such as the comparator 428 of FIG. 4 or the baseband amplifier 504 of FIG. 5. Further, in the configuration 920, the switches 916a-c may be activated (e.g., closed) to couple outputs of the envelope detectors 424e-h to inputs of the envelope detectors 424f-d, respectively. In the configuration 920, the switches 918a-c may be deactivated (e.g., opened) to decouple the envelope detectors 424e-h from the ground node 922.

In the configuration 920, activation of the switches 916a-c may form serial connections between the envelope detectors 424e-g. For example, the switch 916a may form a serial connection between the envelope detectors 424e-f. As additional examples, the switch 916b may form a serial connection between the envelope detectors 424f-g, and the switch 916c may form a serial connection between the envelope detectors 424g-h. The envelope detector 424e may provide a voltage V_{STG,1} to the envelope detector 424f, which may provide a voltage V_{STG,2} to the envelope detector 424g. The envelope detector 424g may provide a voltage V_{STG,3} to the envelope detector 424h.

The configuration 920 may be referred to as, or may correspond to, a four-stage configuration. For example, in the configuration 920, the envelope detectors 424e-g may be coupled to one another via serial connections formed by activation of the switches 914a-c and 916a-c. The configuration 920 may increase gain and increase rise time (and fall time) as compared to the configurations 930 and 940. The configuration 920 may be associated with a gain that is greater than a gain associated with the configuration 930 and that is greater than a gain associated with the configuration 940. Further, the configuration 920 may be associated with a rise time (and fall time) that is greater than a rise time (and fall time) associated with the configuration 930 and that is greater than a rise time (and fall time) associated with the configuration 940.

In the configuration 930, at least some envelope detectors may be coupled to one another via a serial connection. For example, the switch 914a may be deactivated to decouple the output of the envelope detector 424e from the output node 426, and the switch 916a may be activated to couple the output of the envelope detector 424e to the input of the envelope detector 424f. In this example, the envelope detector 424e may be coupled to the envelope detector 424f via a serial connection. As another example, the switch 914c may be deactivated to decouple the output of the envelope detector 424g from the output node 426, and the switch 916c may be activated to couple the output of the envelope detector 424g to the input of the envelope detector 424h. In this example, the envelope detector 424g may be coupled to the envelope detector 424h via a serial connection.

Further, in the configuration 930, at least some envelope detectors may be coupled to one another in parallel. For example, the switch 916b may be deactivated to decouple the output of the envelope detector 424f from the input of the envelope detector 424g, and the switch 914b may be activated to couple the output of the envelope detector 424f to the output node 426. In this example, the envelope detectors 424e-f may be coupled in parallel to the envelope detectors 424g-h. The envelope detector 424e may provide the voltage V_{STG,1} to the envelope detector 424f, and the envelope detector 424g may provide the voltage V_{STG,3} to the envelope detector 424h.

In addition, in the configuration 930, the switches 918a and 918c may be deactivated to decouple the envelope detectors 424f and 424h from the ground node 922. The switch 918b may be activated to couple the envelope detector 424g to the ground node 922.

The configuration 930 may be referred to as, or may correspond to, a two-stage configuration. In a two-stage configuration, multiple envelope detectors 424 may be configurable as a single two-stage envelope detector. For example, in the configuration 930, the envelope detectors 424e-f may be coupled to one another via the switch 916a and may correspond to a first two-stage envelope detector. Further, the envelope detectors 424g-h may be coupled to one another via the switch 916c and may correspond to a second two-stage envelope detector in parallel with the first two-stage detector formed by the envelope detectors 424e-f. The gain associated with the configuration 930 may be less than the gain associated with the configuration 920 and may be greater than the gain associated with the configuration 940. Further, the rise time (and fall time) associated with the configuration 930 may be less than the rise time (and fall time) associated with the configuration 920 and may be greater than the rise time (and fall time) associated with the configuration 940.

In the configuration 940, the envelope detectors 424e-g may be coupled in parallel to one another. For example, the switches 916a-c may be deactivated to decouple outputs of the envelope detectors 424e-h from inputs of the envelope detectors 424f-d, and outputs of the envelope detectors 424e-g may be coupled to the output node 426 (e.g., where the envelope detectors 424e-h are coupled to the output node 426 via the activation of the switches 914a-c). Further, inputs of the envelope detectors 424e-g may be coupled to a ground node (GND) (such as the ground node 922 through switches 918a-c).

The configuration 940 may be referred to as, or may correspond to, a single-stage configuration or a one-stage configuration. For example, in the configuration 940, the envelope detectors 424e-g may be coupled in parallel with one another, which may decrease gain and decrease rise time (and fall time) as compared to the configurations 920 and 930. The gain associated with the configuration 940 may be less than the gain associated with the configuration 920 and may be less than the gain associated with the configuration 930. Further, the rise time (and fall time) associated with the configuration 940 may be less than the rise time (and fall time) associated with the configuration 920 and may be less than the rise time (and fall time) associated with the configuration 930.

In some examples, the AGC circuit 432 may select among any of the configurations of FIG. 9 to adjust one or more of a gain, a rise time, or a fall time associated with the WUR 314. For example, in some implementations, if the gain of the WUR 314 fails to exceed a threshold gain, the AGC circuit 432 may increase the gain, such as by reconfiguring the WUR 314 from the configuration 930 to the configuration 920, or from the configuration 940 to the configuration 920 or the configuration 930. As another example, in some implementations, if the rise time (or fall time) of the WUR 314 exceeds a threshold rise time (or fall time), the AGC circuit 432 may decrease the rise time (or fall time), such as by reconfiguring the WUR 314 from the configuration 920 to the configuration 930 or the configuration 940, or from the configuration 930 to the configuration 940.

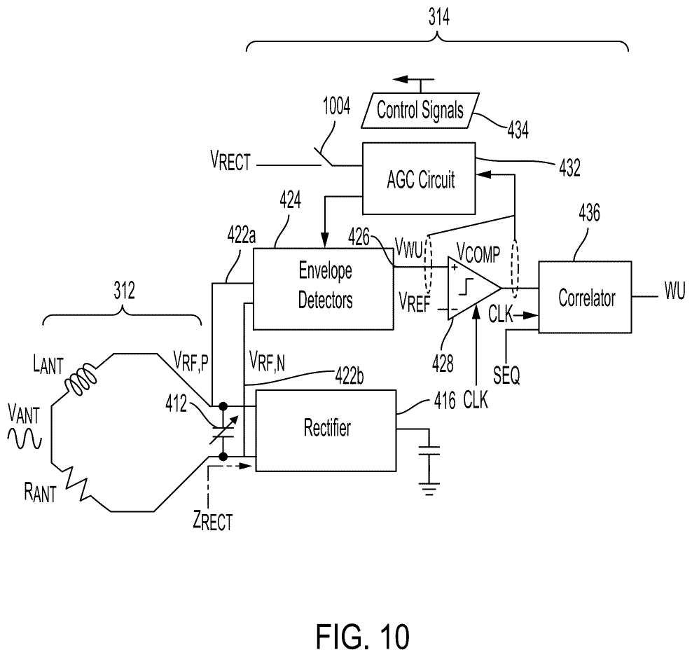

FIG. 10 illustrates another example of a device that includes a WUR 314 with configurable stages. In the example of FIG. 10, a rectifier voltage V_{RECT} may be provided to one or more components of the device, such as the WUR 314. The WUR 314 may be coupled to a switch 1004. In some examples, the device of FIG. 10 may correspond to an Internet-of-Things (IoT) device, such as an ambient IoT device.

During operation, the device of FIG. 10 may perform energy harvesting to generate a harvested energy signal V_{RECT}. The switch 1004 may be enabled when the harvested energy signal V_{RECT} exceeds a threshold voltage level. The harvested energy signal V_{RECT} may be provided to one or more components of the WUR 314. In some examples, at least some energy of the harvested energy signal V_{RECT} may be provided to the AGC circuit 432.

Although certain examples are provided herein for illustration, other examples are also within the scope of the disclosure. For example, in some implementations, the envelope detectors may include a set of one or more differential envelope detectors (such as any of the envelope detectors 424a-d) and may also include a set of one or more single-ended envelope detectors (such as any of the envelope detectors 424e-h). In some such implementations, such different sets of envelope detectors may be selectively activated or deactivated to receive wakeup signals.

Further, some examples herein may illustrate passive envelope detectors. For example, the envelope detectors 424a-d and 424e-h may correspond to passive envelope detectors. As referred to herein, a passive envelope detector may refer to an envelope detector that is configured to operate without direct current (DC) (or with a relatively small amount of DC, such as leakage current) and without being directly connected to a dedicated voltage supply or dedicated voltage “rail” (e.g., VDD).

A controller or other device or circuit described herein may control switches of the envelope detectors 424, such as any of the switches 714a-c, 716a-c, 718a-c, 914a-c, 916a-c, and 918a-c. In some examples, the AGC circuit 432 may provide the control signals 434 to the switches 714a-c, 716a-c, and 718a-c to configure a quantity of stages of the envelope detectors 424. In some examples, the AGC circuit 432 may provide the control signals 434 to the switches 914a-c, 916a-c, and 918a-c to configure a quantity of stages of the envelope detectors 424. The control signals 434 may include a control signal for each switch of the switches 714a-c, 716a-c, and 718a-c or for each switch of the switches 914a-c, 916a-c, and 918a-c. Each such control signal may have a value indicating whether the corresponding switch is to be activated (e.g., closed) or deactivated (e.g., open), such as where a logic one value activates the switch, and where a logic zero value deactivates the switch.

In some aspects, an apparatus includes a plurality of envelope detectors including at least a first passive envelope detector and a second passive envelope detector coupled to the first passive envelope detector. In some examples, the plurality of envelope detectors may include the envelope detectors 424. In some examples, the first passive envelope detector may correspond to one of the envelope detectors envelope detectors 424a-d and 424e-h, and the second passive envelope detector may correspond to another of the envelope detectors 424a-d and 424e-h. The apparatus further includes a plurality of switches configured to couple the first passive envelope detector to the second passive envelope detector as multiple stages in a first configuration and further configured to couple the first passive envelope detector to the second passive envelope detector as a single stage in a second configuration. In some examples, the plurality of switches may include at least some of the switches 714a-c, 716a-c, 718a-c, 914a-c, 916a-c, and 918a-c. In some examples, the first configuration may correspond to one of the configurations 720, 730, 920, or 930, and the second configuration may correspond to one of the configurations 740 or 940.

In some examples, the first passive envelope detector may be coupled to the second passive envelope detector via a serial connection in the first configuration (e.g., via one of the switches 716a-c, as illustrated in the configurations 720, 730, 920, and 930), and the first passive envelope detector may be coupled in parallel to the second passive envelope detector in the second configuration (e.g., as illustrated in the configurations 740 and 940). Further, the first configuration may be associated with a first data rate and a first gain, and the second configuration may be associated with a second data rate that is different than the first data rate and with a second gain that is different than the first gain.

In some implementations, the first passive envelope detector and the second passive envelope detector may each have a differential configuration (e.g., as illustrated in the examples of FIGS. 6 and 7). In accordance with the differential configuration, the first passive envelope detector and the second passive envelope detector may each include a pair of cross-coupled inverters (e.g., where a first inverter formed by the transistors 604, 608 is cross-coupled to a second inverter formed by the transistors 612, 616). The apparatus may further include a first capacitor (e.g., the capacitor 620) having a first terminal coupled to a first input node (e.g., the input node 422a) and further having a second terminal coupled to the first inverter. The apparatus may further include a second capacitor (e.g., the capacitor 624) having a first terminal coupled to a second input node (e.g., the input node 422b) and having a second terminal coupled to the second inverter. The first input node and the second input node may be configured to receive a differential voltage (e.g., the differential voltage V_{RF,P}, V_{RF,N}), and the plurality of envelope detectors are configured to generate a wakeup signal (e.g., the wakeup signal V_{WU}) based on the differential voltage.

In some further examples, the first passive envelope detector and the second passive envelope detector may each have a single-ended configuration (e.g., as illustrated in the examples of FIGS. 8 and 9). In accordance with the single-ended configuration, the first passive envelope detector and the second passive envelope detector may each include a first capacitor (e.g., the capacitor 804), a first transistor (e.g., the transistor 808) coupled to the first capacitor, a second transistor (e.g., the transistor 812) coupled to the first transistor and the first capacitor, and a second capacitor (e.g., the capacitor 816) coupled to the second transistor. The apparatus may further include an input node (e.g., the input node 422) coupled to the first capacitor. The first capacitor may have a first terminal coupled to the input node. The first transistor may have a source terminal coupled to a second terminal of the first capacitor. The second transistor may have a drain terminal and a gate terminal that are coupled to the source terminal of the first transistor and that are further coupled to the second terminal of the first capacitor. The second capacitor may have a first terminal coupled to a source terminal of the second transistor and may also have a second terminal coupled to a ground node (e.g., the ground node 922). The input node may be configured to receive a single-ended voltage (e.g., the single-ended voltage V_{RF}), and the plurality of envelope detectors may be configured to generate a wakeup signal (e.g., the wakeup signal V_{WU}) based on the single-ended voltage.

In some examples, the plurality of switches may include one or more of a first switch coupled to an output of the first passive envelope detector and to an input of the second passive envelope detector, a second switch coupled to the first switch and to an output node of the plurality of envelope detectors, or a third switch coupled to the first switch and to a ground node of the plurality of envelope detectors. In some examples, the first switch may include any of the switches 718a-c or any of the switches 918a-c. In some examples, the second switch may include any of the switches 716a-c or any of the switches 916a-c. In some examples, the third switch may include any of the switches 718a-c or any of the switches 918a-c.

In some examples, the apparatus may include an automatic gain control (AGC) circuit coupled to the plurality of switches. The AGC circuit may correspond to the AGC circuit 432. The AGC circuit may be configured to provide a plurality of control signals to the plurality of switches to select either the first configuration or the second configuration. The plurality of control signals may include or may correspond to the control signals 434.

In some examples, the apparatus may further include a wakeup circuit (e.g., the WUR 314) that includes the plurality of envelope detectors and the plurality of switches. The apparatus may also include an antenna (e.g., any of the antennas 234a-t, 252a-r, or 312) that is coupled to the wakeup circuit and that is configured to receive a signal (e.g., the signal VANT). The apparatus may further include a rectifier (e.g., the rectifier 416) coupled to the wakeup circuit. The rectifier may be configured to generate harvested energy (e.g., the harvested energy signal V_{RECT}) based at least in part on the signal. In some examples, the apparatus includes or corresponds to an ambient Internet-of-Things (IoT) device that includes the wakeup circuit.

As referred to herein, a “single stage” may refer to a single envelope detector or to multiple envelope detectors that are coupled to one another in parallel. As referred to herein, “multiple stages” may refer to multiple envelope detectors that are coupled to one another via one or more serial connections. As referred to herein, a “differential configuration” may refer to circuitry that is configured to operate using one or more pairs of differential voltages. As referred to herein, a “single-ended configuration” may refer to circuitry that is configured to operate using one or more single-ended voltages.

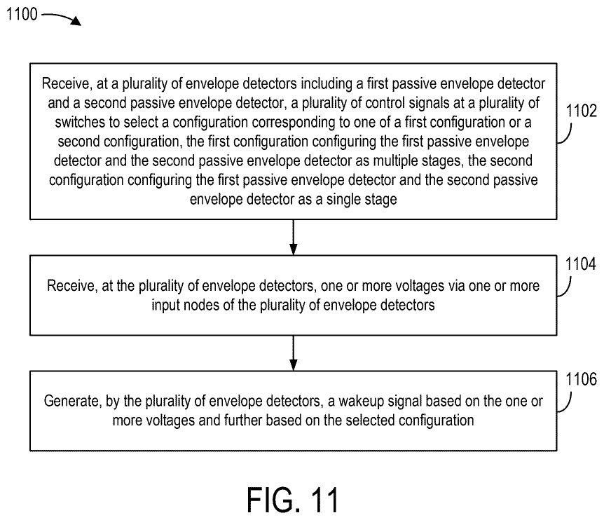

FIG. 11 is a flow chart illustrating an example of a method 1100 of operation of a device that includes configurable envelope detectors. In some examples, the method 1100 may be performed by a receiver, such as the receiver circuit 300.

The method 1100 includes receiving, at a plurality of envelope detectors including a first passive envelope detector and a second passive envelope detector, a plurality of control signals at a plurality of switches to select a configuration corresponding to one of a first configuration or a second configuration, at 1102. The first configuration configures the first passive envelope detector and the second passive envelope detector as multiple stages, and the second configuration configures the first passive envelope detector and the second passive envelope detector as a single stage. In some examples, the first passive envelope detector may correspond to one of the envelope detectors 424, and the second passive envelope detector may correspond to another of the envelope detectors 424. In some examples, the control signals may correspond to the control signals 434, and the switches may include any of switches 714a-c, 716a-c, and 718a-c or any of the switches 914a-c, 916a-c, and 918a-c.

The method 1100 further includes receiving, at the plurality of envelope detectors, one or more voltages via one or more input nodes of the plurality of envelope detectors, at 1104. In some examples, the one or more voltages may correspond to the differential voltages V_{RF,P} and V_{RF,N}. In some other examples, the one or more voltages may correspond to the single-ended voltage V_{RF}.

The method 1100 further includes generating, by the plurality of envelope detectors, a wakeup signal based on the one or more voltages and further based on the selected configuration, at 1106. In some examples, the wakeup signal may correspond to the wakeup signal V_{WU}.

In some aspects, an apparatus includes first means for passive envelope detection (e.g., one of the envelope detectors 424) and second means for passive envelope detection (e.g., another of the envelope detectors 424). The apparatus further includes means for coupling (e.g., any of switches 714a-c, 716a-c, and 718a-c or any of the switches 914a-c, 916a-c, and 918a-c) the first means for passive envelope detection to the second means for passive envelope detection as multiple stages in a first configuration and for coupling the first means for passive envelope detection to the second means for passive envelope detection as a single stage in a second configuration.

In some implementations, the first means for passive envelope detection and the second means for passive envelope detection may be configurable as a first two-stage envelope detector. The apparatus may further include third means for passive envelope detection (e.g., another of the envelope detectors 424) and fourth means for passive envelope detection (e.g., another of the envelope detectors 424). The third means for passive envelope detection and the fourth means for passive envelope detection may be configurable as a second two-stage envelope detector in parallel with the first two-stage envelope detector.

One or more features herein may improve performance associated with a receiver. For example, by configuring a quantity of stages of the WUR 314, one or more receiver parameters of the WUR 314 may be adjusted. The one or more receiver parameters may include, for example, one or more of a gain, a rise time, a fall time, or a data rate associated with the WUR 314. Further, in some aspects, the one or more receiver parameters may be adjustable without changing (or without substantially changing) some other characteristics of the WUR 314, such as one or more of a power consumption of the WUR 314 or an input impedance matching of the WUR 314. For example, a first configuration of the WUR 314 may be associated with a first quantity of stages and a first gain, and a second configuration of the WUR 314 may be associated with a second quantity of stages different than the first quantity and with a second gain different than the first gain. As another example, the first configuration may be associated with a first data rate, and the second configuration may be associated with a second data rate that is different than the first data rate. In some implementations, the first configuration and the second configuration may be associated with one or more of a common power consumption of the WUR 314 or a common input impedance matching of the WUR 314. In some examples, by changing envelope detector rise and fall times associated with the WUR 314, a data rate (or allowable data rate) of the WUR 314 may be adjusted (e.g., without substantially changing a power consumption or input impedance matching of the WUR 314). As a result, performance of the WUR 314 may be improved without increasing a bandwidth-to-gain product of the WUR 314 or a power consumption of the WUR 314. Further, the WUR 314 may be compatible with a variety of implementations and operating conditions, such as varying interference, channel quality, process corners, temperature, and other conditions.

Further, by using passive envelope detectors, power consumption can be reduced. For example, passive envelope detectors may operate without direct current (DC) (or with a relatively small amount of DC, such as leakage current) and without being directly connected to a dedicated voltage supply or dedicated voltage “rail” (e.g., V_{DD}). As a result, power consumption of the WUR 314 may be reduced as compared to some other receivers, such as receivers that use active envelope detectors, which may operate using DC and which may consume a relatively large amount of power.

In addition, some features described herein may support analog gain control or mixed gain control (where gain control is performed using both analog and digital techniques) for the WUR 314. Such analog or mixed gain control may be performed via a programmable gain amplifier (PGA), which may correspond to the AGC circuit 432. To illustrate, in some implementations, the AGC circuit 432 may correspond to or may include an active PGA that consumes DC power via a voltage “rail” (e.g., VDD). The gain of the PGA may be varied through an analog bias voltage or via digital control using switches or other components in and out of the amplifier circuit. In some implementations, such analog or mixed gain control may improve gain control as compared to other techniques that utilize digital-only control (e.g., by enabling a “finer” gain control as compared to a “coarse” digital-only gain control).

In a first aspect, an apparatus includes a plurality of envelope detectors including at least a first passive envelope detector and a second passive envelope detector coupled to the first passive envelope detector. The apparatus further includes a plurality of switches configured to couple the first passive envelope detector to the second passive envelope detector as multiple stages in a first configuration. The plurality of switches is further configured to couple the first passive envelope detector to the second passive envelope detector as a single stage in a second configuration.

In a second aspect, in combination with the first aspect, the first passive envelope detector is coupled to the second passive envelope detector via a serial connection in the first configuration, and the first passive envelope detector is coupled in parallel to the second passive envelope detector in the second configuration.

In a third aspect, in combination with one or more of the first aspect or the second aspect, the first passive envelope detector and the second passive envelope detector are configurable as a first two-stage envelope detector, and the plurality of envelope detectors further include a third passive envelope detector and a fourth passive envelope detector that are configurable as a second two-stage envelope detector in parallel with the first two-stage envelope detector.

In a fourth aspect, in combination with one or more of the first aspect through the third aspect, the first configuration is associated with a first data rate, and the second configuration is associated with a second data rate that is different than the first data rate.

In a fifth aspect, in combination with one or more of the first aspect through the fourth aspect, the first passive envelope detector and the second passive envelope detector each have a differential configuration, and in accordance with the differential configuration, at least the first passive envelope detector includes a first inverter and a second inverter that is cross-coupled to the first inverter.

In a sixth aspect, in combination with one or more of the first aspect through the fifth aspect, the apparatus further includes a first capacitor and a second capacitor. The first capacitor has a first terminal coupled to a first input node and further has a second terminal coupled to the first inverter. The second capacitor has a first terminal coupled to a second input node and further has a second terminal coupled to the second inverter.

In a seventh aspect, in combination with one or more of the first aspect through the sixth aspect, the first input node and the second input node are configured to receive a differential voltage, and the plurality of envelope detectors are configured to generate a wakeup signal based on the differential voltage.

In an eighth aspect, in combination with one or more of the first aspect through the seventh aspect, the first passive envelope detector and the second passive envelope detector each have a single-ended configuration, and in accordance with the single-ended configuration, the first passive envelope detector and the second passive envelope detector each include a first capacitor, a first transistor, a second transistor, and a second capacitor. The first capacitor has a first terminal coupled to an input node. The first transistor has a source terminal coupled to a second terminal of the first capacitor. The second transistor has a drain terminal and a gate terminal that are coupled to the source terminal of the first transistor and that are further coupled to the second terminal of the first capacitor. The second capacitor has a first terminal coupled to a source terminal of the second transistor and further has a second terminal coupled to a ground node.

In a ninth aspect, in combination with one or more of the first aspect through the eighth aspect, the input node is configured to receive a single-ended voltage, and the plurality of envelope detectors are configured to generate a wakeup signal based on the single-ended voltage.

In a tenth aspect, in combination with one or more of the first aspect through the ninth aspect, the plurality of switches includes one or more of a first switch coupled to an output of the first passive envelope detector and to an input of the second passive envelope detector, a second switch coupled to the first switch and to an output node of the plurality of envelope detectors, or a third switch coupled to the first switch and to a ground node of the plurality of envelope detectors.

In an eleventh aspect, in combination with one or more of the first aspect through the tenth aspect, the apparatus further includes an automatic gain control (AGC) circuit coupled to the plurality of switches.

In a twelfth aspect, in combination with one or more of the first aspect through the eleventh aspect, the AGC circuit is configured to provide a plurality of control signals to the plurality of switches to select either the first configuration or the second configuration.

In a thirteenth aspect, a method includes receiving, at a plurality of envelope detectors including a first passive envelope detector and a second passive envelope detector, a plurality of control signals at a plurality of switches to select a configuration corresponding to one of a first configuration or a second configuration. The first configuration configures the first passive envelope detector and the second passive envelope detector as multiple stages, and the second configuration configures the first passive envelope detector and the second passive envelope detector as a single stage. The method further includes receiving, at the plurality of envelope detectors, one or more voltages via one or more input nodes of the plurality of envelope detectors. The method further includes generating, by the plurality of envelope detectors, a wakeup signal based on the one or more voltages and further based on the selected configuration.

In a fourteenth aspect, in combination with the thirteenth aspect, the method further includes coupling the first passive envelope detector to the second passive envelope detector via a serial connection in the first configuration based on the plurality of control signals.

In a fifteenth aspect, in combination with one or more of the thirteenth aspect through the fourteenth aspect, the method further includes coupling the first passive envelope detector in parallel to the second passive envelope detector in the second configuration based on the plurality of control signals.

In a sixteenth aspect, in combination with one or more of the thirteenth aspect through the fifteenth aspect, the method further includes configuring the first passive envelope detector and the second passive envelope detector as a first two-stage envelope detector.

In a seventeenth aspect, in combination with one or more of the thirteenth aspect through the sixteenth aspect, the method further includes configuring a third passive envelope detector of the plurality of envelope detectors and a fourth passive envelope detector of the plurality of envelope detectors as a second two-stage envelope detector in parallel with the first two-stage envelope detector.

In an eighteenth aspect, in combination with one or more of the thirteenth aspect through the seventeenth aspect, the first configuration is associated with a first data rate, and the second configuration is associated with a second data rate that is different than the first data rate.

In a nineteenth aspect, in combination with one or more of the thirteenth aspect through the eighteenth aspect, the first passive envelope detector and the second passive envelope detector each have a differential configuration.

In a twentieth aspect, in combination with one or more of the first aspect through the nineteenth aspect, in accordance with the differential configuration, the one or more voltages correspond to a differential voltage.

In a twenty-first aspect, in combination with one or more of the thirteenth aspect through the twentieth aspect, the first passive envelope detector and the second passive envelope detector each have a single-ended configuration.

In a twenty-second aspect, in combination with one or more of the thirteenth aspect through the twenty-first aspect, in accordance with the single-ended configuration, the one or more voltages correspond to a single-ended voltage.

In a twenty-third aspect, an apparatus includes first means for passive envelope detection and second means for passive envelope detection. The apparatus further includes means for coupling the first means for passive envelope detection to the second means for passive envelope detection as multiple stages in a first configuration and for coupling the first means for passive envelope detection to the second means for passive envelope detection as a single stage in a second configuration.

In a twenty-fourth aspect, in combination with the twenty-third aspect, the first means for passive envelope detection is coupled to the second means for passive envelope detection via a serial connection in the first configuration, and the first means for passive envelope detection is coupled in parallel to the second means for passive envelope detection in the second configuration.

In a twenty-fifth aspect, in combination with one or more of the twenty-third aspect through the twenty-fourth aspect, the first means for passive envelope detection and the second means for passive envelope detection are configurable as a first two-stage envelope detector.

In a twenty-sixth aspect, in combination with one or more of the twenty-third aspect through the twenty-fifth aspect, the apparatus further includes third means for passive envelope detection and fourth means for passive envelope detection. The third means for passive envelope detection and the fourth means for passive envelope detection are configurable as a second two-stage envelope detector in parallel with the first two-stage envelope detector.

In a twenty-seventh aspect, in combination with one or more of the twenty-third aspect through the twenty-sixth aspect, the first configuration is associated with a first data rate, and the second configuration is associated with a second data rate that is different than the first data rate.

In a twenty-eighth aspect, in combination with one or more of the twenty-third aspect through the twenty-seventh aspect, the first means for passive envelope detection and the second means for passive envelope detection each have a differential configuration.

In a twenty-ninth aspect, in combination with one or more of the twenty-third aspect through the twenty-eighth aspect, in accordance with the differential configuration, the first means for passive envelope detection and the second means for passive envelope detection are configured to receive a differential voltage and to generate a wakeup signal based on the differential voltage.

In a thirtieth aspect, in combination with one or more of the twenty-third aspect through the twenty-ninth aspect, the first means for passive envelope detection and the second means for passive envelope detection each have a single-ended configuration.

In a thirty-first aspect, in combination with one or more of the first aspect through the thirtieth aspect, in accordance with the single-ended configuration, the first means for passive envelope detection and the second means for passive envelope detection are configured to receive a single-ended voltage and to generate a wakeup signal based on the single-ended voltage.

In a thirty-second aspect, in combination with one or more of the first aspect through the twelfth aspect, the first configuration is associated with a first gain, and the second configuration is associated with a second gain that is different than the first gain.

In a thirty-third aspect, in combination with one or more of the first aspect through the twelfth aspect and the thirty-second aspect, the apparatus further includes a wakeup circuit that includes the plurality of envelope detectors and the plurality of switches.

In a thirty-fourth aspect, in combination with one or more of the first aspect through the twelfth aspect and the thirty-second aspect through thirty-fourth aspect, the apparatus further includes an antenna coupled to the wakeup circuit and configured to receive a signal. The apparatus further includes a rectifier coupled to the wakeup circuit. The rectifier is configured to generate harvested energy based at least in part on the signal.

In a thirty-fifth aspect, in combination with one or more of the first aspect through the twelfth aspect and the thirty-second aspect through thirty-fifth aspect, the apparatus further includes an ambient Internet-of-Things (IoT) device that includes the wakeup circuit.

In a thirty-sixth aspect, in combination with one or more of the thirteenth aspect through the twenty-second aspect, the first configuration is associated with a first gain, and the second configuration is associated with a second gain that is different than the first gain.

In a thirty-seventh aspect, in combination with one or more of the twenty-third aspect through the thirty-first aspect, the first configuration is associated with a first gain, and the second configuration is associated with a second gain that is different than the first gain.

In the figures, a single block may be described as performing a function or functions. The function or functions performed by that block may be performed in a single component or across multiple components, and/or may be performed using hardware, software, or a combination of hardware and software. To illustrate, various illustrative components, blocks, modules, circuits, and operations may be described in terms of functionality. Whether such functionality is implemented as hardware or software may depend upon the particular application and the overall system design. Skilled artisans may implement the described functionality in varying ways for each particular application, but such implementation decisions should not be interpreted as causing a departure from the scope of the disclosure. Also, the example devices may include components other than those shown, including components such as a processor, memory, and the like.

As used herein, the term “determine” or “determining” encompasses a wide variety of actions and, therefore, “determining” can include calculating, computing, processing, deriving, estimating, investigating, looking up (such as via looking up in a table, a database, or another data structure), inferring, ascertaining, or measuring, among other possibilities. Also, “determining” can include receiving (such as receiving information), accessing (such as accessing data stored in memory) or transmitting (such as transmitting information), among other possibilities. Additionally, “determining” can include resolving, selecting, obtaining, choosing, establishing and other such similar actions.

The terms “device” and “apparatus” are not limited to one or a specific number of physical objects (such as one smartphone, one camera controller, one processing system, and so on). As used herein, a device may be any electronic device with one or more parts that may implement at least some portions of the disclosure. While the description and examples herein use the term “device” to describe various aspects of the disclosure, the term “device” is not limited to a specific configuration, type, or number of objects. As used herein, an apparatus may include a device or a portion of the device for performing the described operations.

Certain components in a device or apparatus described as “means for accessing,” “means for receiving,” “means for sending,” “means for using,” “means for selecting,” “means for determining,” “means for normalizing,” “means for multiplying,” or other similarly-named terms referring to one or more operations on data, such as image data, may refer to processing circuitry (such as application specific integrated circuits (ASICs), digital signal processors (DSP), graphics processing unit (GPU), central processing unit (CPU), computer vision processor (CVP), or neural signal processor (NSP)) configured to perform the recited function through hardware, software, or a combination of hardware configured by software.

Those of skill in the art would understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

One or more components, functional blocks, and modules described herein may include processors, electronics devices, hardware devices, electronics components, logical circuits, memories, software codes, firmware codes, among other examples, or any combination thereof. Software shall be construed broadly to mean instructions, instruction sets, code, code segments, program code, programs, subprograms, software modules, application, software applications, software packages, routines, subroutines, objects, executables, threads of execution, procedures, and/or functions, among other examples, whether referred to as software, firmware, middleware, microcode, hardware description language or otherwise. In addition, features discussed herein may be implemented via specialized processor circuitry, via executable instructions, or combinations thereof.

In one or more aspects, the operations described may be implemented in hardware, digital electronic circuitry, computer software, firmware, including the structures disclosed in this specification and their structural equivalents thereof, or in any combination thereof. Implementations of the subject matter described in this specification also may be implemented as one or more computer programs, which is one or more modules of computer program instructions, encoded on a computer storage media for execution by, or to control the operation of, data processing apparatus.

The operations of a method or process disclosed herein may be implemented in a processor-executable software module which may reside on a computer-readable medium and commercially made available as a computer program product as software. Computer-readable media includes both computer storage media and communication media including any medium that may be enabled to transfer a computer program from one place to another. A storage media may be any available media that may be accessed by a computer. By way of example, and not limitation, such computer-readable media may include random-access memory (RAM), read-only memory (ROM), electrically erasable programmable read-only memory (EEPROM), CD-ROM or other optical disk storage, magnetic disk storage or other magnetic storage devices, or any other medium that may be used to store desired program code in the form of instructions or data structures and that may be accessed by a computer. Also, any connection may be properly termed a computer-readable medium. Disk and disc, as used herein, includes compact disc (CD), laser disc, optical disc, digital versatile disc (DVD), floppy disk, and Blu-ray disc, where disks usually reproduce data magnetically and discs reproduce data optically with lasers. Combinations of the above should also be included within the scope of computer-readable media.

Various modifications to the implementations described in this disclosure may be readily apparent to those skilled in the art, and the generic principles defined herein may be applied to some other implementations without departing from the spirit or scope of this disclosure. Thus, the claims are not intended to be limited to the implementations shown herein but are to be accorded the widest scope consistent with this disclosure, the principles and the novel features disclosed herein.

Additionally, a person having ordinary skill in the art will readily appreciate, opposing terms such as “upper” and “lower,” or “front” and back,” or “top” and “bottom,” or “forward” and “backward,” or “left” and “right” are sometimes used for ease of describing the figures, and indicate relative positions corresponding to the orientation of the figure on a properly oriented page, and may not reflect the proper orientation of any device as implemented.

Certain features that are described in this specification in the context of separate implementations also may be implemented in combination in a single implementation. Conversely, various features that are described in the context of a single implementation also may be implemented in multiple implementations separately or in any suitable subcombination. Moreover, although features may be described above as acting in certain combinations and even initially claimed as such, one or more features from a claimed combination may in some cases be excised from the combination, and the claimed combination may be directed to a subcombination or variation of a subcombination.

Similarly, while operations are depicted in the drawings in a particular order, this should not be understood as requiring that such operations be performed in the particular order shown, or in sequential order, or that all illustrated operations be performed to achieve desirable results. Further, the drawings may schematically depict one or more example processes in the form of a flow diagram. However, other operations that are not depicted may be incorporated in the example processes that are schematically illustrated. For example, one or more additional operations may be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems may generally be integrated together in a single software product or packaged into multiple software products. Additionally, some other implementations are within the scope of the following claims. In some cases, the actions recited in the claims may be performed in a different order and still achieve desirable results.

As used herein, including in the claims, the term “or,” when used in a list of two or more items, means that any one of the listed items may be employed by itself, or any combination of two or more of the listed items may be employed. For example, if a composition is described as containing components A, B, or C, the composition may contain A alone; B alone; C alone; A and B in combination; A and C in combination; B and C in combination; or A, B, and C in combination. Also, as used herein, including in the claims, “or” as used in a list of items prefaced by “at least one of” indicates a disjunctive list such that, for example, a list of “at least one of A, B, or C” means A or B or C or AB or AC or BC or ABC (that is A and B and C) or any of these in any combination thereof.

As used herein, “based on” is intended to be interpreted in the inclusive sense, unless otherwise explicitly indicated. For example, “based on” may be used interchangeably with “based at least in part on,” “associated with,” “in association with,” or “in accordance with” unless otherwise explicitly indicated. Specifically, unless a phrase refers to “based on only ‘a,’” or the equivalent in context, whatever it is that is “based on ‘a,’” or “based at least in part on ‘a,’” may be based on “a” alone or based on a combination of “a” and one or more other factors, conditions, or information.

The term “substantially” is defined as largely, but not necessarily wholly, what is specified (and includes what is specified; for example, substantially 90 degrees includes 90 degrees and substantially parallel includes parallel), as understood by a person of ordinary skill in the art. In any disclosed implementations, the term “substantially” may be substituted with “within [a percentage] of” what is specified, where the percentage includes 0.1, 5, 5, or 50 percent.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein but is to be accorded the widest scope consistent with the principles and novel features disclosed herein.

What is claimed is:

1. An apparatus comprising:
a plurality of envelope detectors including at least a first passive envelope detector and a second passive envelope detector coupled to the first passive envelope detector; and
a plurality of switches configured to couple the first passive envelope detector to the second passive envelope detector as multiple stages in a first configuration and further configured to couple the first passive envelope detector to the second passive envelope detector as a single stage in a second configuration.

2. The apparatus of claim 1, wherein the first passive envelope detector is coupled to the second passive envelope detector via a serial connection in the first configuration, and wherein the first passive envelope detector is coupled in parallel to the second passive envelope detector in the second configuration.

3. The apparatus of claim 1, wherein the first passive envelope detector and the second passive envelope detector are configurable as a first two-stage envelope detector, and wherein the plurality of envelope detectors further include a third passive envelope detector and a fourth passive envelope detector that are configurable as a second two-stage envelope detector in parallel with the first two-stage envelope detector.

4. The apparatus of claim 1, wherein the first configuration is associated with a first data rate, and wherein the second configuration is associated with a second data rate that is different than the first data rate.

5. The apparatus of claim 1, wherein the first configuration is associated with a first gain, and wherein the second configuration is associated with a second gain that is different than the first gain.

6. The apparatus of claim 1, wherein the first passive envelope detector and the second passive envelope detector each have a differential configuration, and wherein, in accordance with the differential configuration, at least the first passive envelope detector includes a first inverter and a second inverter that is cross-coupled to the first inverter.

7. The apparatus of claim 6, further comprising:
a first capacitor having a first terminal coupled to a first input node and further having a second terminal coupled to the first inverter; and
a second capacitor having a first terminal coupled to a second input node and further having a second terminal coupled to the second inverter.

8. The apparatus of claim 7, wherein the first input node and the second input node are configured to receive a differential voltage, and wherein the plurality of envelope detectors are configured to generate a wakeup signal based on the differential voltage.

9. The apparatus of claim 1, wherein the first passive envelope detector and the second passive envelope detector each have a single-ended configuration, and wherein, in accordance with the single-ended configuration, the first passive envelope detector and the second passive envelope detector each include:
a first capacitor having a first terminal coupled to an input node;
a first transistor having a source terminal coupled to a second terminal of the first capacitor;
a second transistor having a drain terminal and a gate terminal that are coupled to the source terminal of the first transistor and that are further coupled to the second terminal of the first capacitor; and
a second capacitor having a first terminal coupled to a source terminal of the second transistor and further having a second terminal coupled to a ground node.

10. The apparatus of claim 9, wherein the input node is configured to receive a single-ended voltage, and wherein the plurality of envelope detectors are configured to generate a wakeup signal based on the single-ended voltage.

11. The apparatus of claim 1, wherein the plurality of switches includes one or more of:
a first switch coupled to an output of the first passive envelope detector and to an input of the second passive envelope detector;
a second switch coupled to the first switch and to an output node of the plurality of envelope detectors; or
a third switch coupled to the first switch and to a ground node of the plurality of envelope detectors.

12. The apparatus of claim 1, further comprising an automatic gain control (AGC) circuit coupled to the plurality of switches.

13. The apparatus of claim 12, wherein the AGC circuit is configured to provide a plurality of control signals to the plurality of switches to select either the first configuration or the second configuration.

14. The apparatus of claim 1, further comprising a wakeup circuit that includes the plurality of envelope detectors and the plurality of switches.

15. The apparatus of claim 14, further comprising:
an antenna coupled to the wakeup circuit and configured to receive a signal; and
a rectifier coupled to the wakeup circuit, wherein the rectifier is configured to generate harvested energy based at least in part on the signal.

16. The apparatus of claim 14, further comprising an ambient Internet-of-Things (IoT) device that includes the wakeup circuit.

17. A method comprising:
receiving, at a plurality of envelope detectors including a first passive envelope detector and a second passive envelope detector, a plurality of control signals at a plurality of switches to select a configuration corresponding to one of a first configuration or a second configuration, the first configuration configuring the first passive envelope detector and the second passive envelope detector as multiple stages, the second configuration configuring the first passive envelope detector and the second passive envelope detector as a single stage;
receiving, at the plurality of envelope detectors, one or more voltages via one or more input nodes of the plurality of envelope detectors; and
generating, by the plurality of envelope detectors, a wakeup signal based on the one or more voltages and further based on the selected configuration.

18. The method of claim 17, further comprising coupling the first passive envelope detector to the second passive envelope detector via a serial connection in the first configuration based on the plurality of control signals.

19. The method of claim 17, further comprising coupling the first passive envelope detector in parallel to the second passive envelope detector in the second configuration based on the plurality of control signals.

20. The method of claim 17, further comprising configuring the first passive envelope detector and the second passive envelope detector as a first two-stage envelope detector.

21. The method of claim 20, further comprising configuring a third passive envelope detector of the plurality of envelope detectors and a fourth passive envelope detector of the plurality of envelope detectors as a second two-stage envelope detector in parallel with the first two-stage envelope detector.

22. The method of claim 17, wherein the first configuration is associated with a first data rate, and wherein the second configuration is associated with a second data rate that is different than the first data rate.

23. The method of claim 17, wherein the first configuration is associated with a first gain, and wherein the second configuration is associated with a second gain that is different than the first gain.

24. The method of claim 17, wherein the first passive envelope detector and the second passive envelope detector each have a differential configuration, and wherein, in accordance with the differential configuration, the one or more voltages correspond to a differential voltage.

25. The method of claim 17, wherein the first passive envelope detector and the second passive envelope detector each have a single-ended configuration, and wherein, in accordance with the single-ended configuration, the one or more voltages correspond to a single-ended voltage.

26. An apparatus comprising:
first means for passive envelope detection;
second means for passive envelope detection; and
means for coupling the first means for passive envelope detection to the second means for passive envelope detection as multiple stages in a first configuration and for coupling the first means for passive envelope detection to the second means for passive envelope detection as a single stage in a second configuration.

27. The apparatus of claim 26, wherein the first means for passive envelope detection is coupled to the second means for passive envelope detection via a serial connection in the first configuration, and wherein the first means for passive envelope detection is coupled in parallel to the second means for passive envelope detection in the second configuration.

28. The apparatus of claim 26, wherein the first means for passive envelope detection and the second means for passive envelope detection are configurable as a first two-stage envelope detector.

29. The apparatus of claim 28, further comprising:
third means for passive envelope detection; and
fourth means for passive envelope detection,
wherein the third means for passive envelope detection and the fourth means for passive envelope detection are configurable as a second two-stage envelope detector in parallel with the first two-stage envelope detector.

30. The apparatus of claim 26, wherein the first configuration is associated with a first data rate and with a first gain, and wherein the second configuration is associated with a second data rate that is different than the first data rate and with a second gain that is different than the first gain.
